(19) United States
(12) Patent Application Publication
(10) Pub. No.: US 2024/0357859 A1
(43) Pub. Date: Oct. 24, 2024

(54) DISPLAY PANEL AND MANUFACTURING METHOD

(71) Applicant: Samsung Display Co., Ltd., Yongin-Si (KR)

(72) Inventor: JINHO JU, Yongin-si (KR)

(21) Appl. No.: 18/402,733

(22) Filed: Jan. 3, 2024

(30) Foreign Application Priority Data
Apr. 18, 2023 (KR) 10-2023-0050617

(51) Int. Cl. H10K 59/121; H10K 59/12; H10K 59/131; H10K 71/60; H10K 102/00

(52) U.S. Cl. CPC H10K 59/1213; H10K 59/1201; H10K 59/131; H10K 71/60; H10K 2102/311

(57) ABSTRACT

Provided is a display panel including a base layer, a transistor disposed on the base layer and including a semiconductor pattern and a gate, an organic layer disposed on the transistor, a plurality of inorganic layers disposed between the transistor and the inorganic layer, a first conductive pattern disposed between the inorganic layers, an organic light emitting element disposed on the organic layer, and a first opening extending through at least one of the inorganic layers, wherein the first opening is characterized by an absence of an inorganic layer material, and does not overlap the first conductive pattern and the transistor.

### CROSS-REFERENCE TO RELATED APPLICATIONS

This U.S. non-provisional patent application claims priority, under 35 U.S.C. § 119, to Korean Patent Application No. 10-2023-0050617 filed on Apr. 18, 2023, the entire contents of which are hereby incorporated by reference.

### BACKGROUND

The present disclosure herein relates to a display panel and a method for manufacturing the same, and more particularly to a display panel with improved durability and a method for manufacturing the same.

A display device is activated by an electrical signal. The display device can be composed of a display panel for displaying an image, and various layers such as an input sensing layer for sensing an external input. Pixels of the display device may be electrically connected to each other by variously arranged signal lines.

### SUMMARY

The present disclosure provides a display panel with improved durability and a method for manufacturing the display panel.

One aspect of the inventive concept provides a display panel including a base layer, a transistor disposed on the base layer and including a semiconductor pattern and a gate, an organic layer disposed on the transistor, a plurality of inorganic layers disposed between the transistor and the organic layer, a first conductive pattern disposed on any one of the inorganic layers, and an organic light emitting element disposed on the organic layer, wherein a first opening passing through at least one of the inorganic layers is defined, wherein the first opening does not overlap the first conductive pattern and the transistor on a plane.

The transistor may be provided in plurality, and the first opening may be positioned between adjacent transistors of the plurality of transistors.

The display panel may further include a plurality of pixel circuits, each of which includes the transistors, and a second opening positioned between adjacent pixel circuits of the plurality of pixel circuits.

The first opening may include a lower opening defined in a first inorganic layer of the inorganic layers, and an upper opening defined in a second inorganic layer disposed on the first inorganic layer of the inorganic layers, the upper opening being connected to the lower opening, wherein the diameter of the upper opening may be greater than or equal to the diameter of the lower opening.

One edge of the gate or one edge of the first conductive pattern may be aligned with a wall of the upper opening.

The gate and the first conductive pattern may be disposed on the same layer, and one side of the gate and one side of the first conductive pattern may be aligned with a wall of the upper opening.

The transistor may include a first transistor including a first semiconductor pattern, a first gate, and an upper electrode, and a second transistor disposed spaced apart from the first transistor and including a second semiconductor pattern and a second gate, and the inorganic layers comprise first to sixth layers sequentially stacked on the base layer, wherein the first semiconductor pattern may be disposed on the first layer, the first gate may be disposed on the second layer, the upper electrode may be disposed on the third layer, the second semiconductor pattern may be disposed on the fourth layer, and the second gate may be disposed on the fifth layer.

The first semiconductor pattern may include polysilicon, and the second semiconductor pattern may include an oxide.

The display panel may further include a lower conductive layer overlapping the first semiconductor pattern, and disposed between the base layer and the first layer.

The display panel may further include an organic material covering the first opening.

The organic material may be in direct contact with the first opening.

The base layer may include a folding region that is adjacent to a folding axis, and a non-folding region across the folding region from the folding axis, wherein at least a portion of the first opening may extend in a direction parallel to the folding axis.

In an embodiment, the display panel may further include a second conductive pattern disposed on any one among the inorganic layers, and spaced apart from the first conductive pattern, wherein the first opening may be positioned between the first conductive pattern and the second conductive pattern.

In another aspect of the inventive concept, a method for manufacturing a display panel includes forming a transistor on a base layer, forming inorganic layers on the base layer, forming a first conductive pattern on any one among the inorganic layers, forming an organic layer on the inorganic layers, and forming an opening passing through at least one among the inorganic layers, and not overlapping the transistor and the first conductive pattern, wherein the forming of the opening is performed before the forming of the organic layer on the inorganic layers.

The forming of the opening may include etching a first inorganic layer among the inorganic layers to form a lower opening, and etching a second inorganic layer disposed on the first inorganic layer to form an upper opening overlapping the lower opening.

A half-tone mask may be used to form the upper opening having a diameter different from that of the lower opening.

The first conductive pattern may be used as a mask to etch at least one among the inorganic layers, thereby forming the opening.

The first conductive pattern and the opening may be simultaneously formed.

The forming of the transistor may include forming a semiconductor pattern on a first inorganic layer of the inorganic layers, forming a second inorganic layer on the first inorganic layer, and forming a gate on the second inorganic layer, wherein the forming of the opening may further include etching the second inorganic layer by using the gate as a mask.

The forming of the transistor may include forming a semiconductor pattern on a first inorganic layer of the inorganic layers, forming a second inorganic layer on the first inorganic layer, and forming a gate on the second inorganic layer, wherein the gate and the opening may be simultaneously formed.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1A is a perspective view of an unfolded state of a display device according to an embodiment of the inventive concept;

FIG. 1B is a perspective view of a folded state of a display device according to an embodiment of the inventive concept;

FIG. 2 is a cross-sectional view of a display device according to an embodiment of the inventive concept;

FIG. 3 is a block diagram of a display device according to an embodiment of the inventive concept;

FIG. 4 is an equivalent circuit diagram of a pixel according to an embodiment of the inventive concept;

FIG. 5 is a cross-sectional view of a display module according to an embodiment of the inventive concept;

FIG. 6A and FIG. 6B are plan views of adjacent pixels according to an embodiment of the inventive concept;

FIG. 7 is a plan view of adjacent pixels according to an embodiment of the inventive concept;

FIG. 8A to FIG. 8C are cross-sectional views of a preliminary display panel according to an embodiment of the inventive concept;

FIG. 9A to FIG. 9C are cross-sectional views of a preliminary display panel according to an embodiment of the inventive concept;

FIG. 10A to FIG. 10C are cross-sectional views of a preliminary display panel according to an embodiment of the inventive concept;

FIG. 11A to FIG. 11C are cross-sectional views of a preliminary display panel according to an embodiment of the inventive concept; and

FIG. 12A and FIG. 12B are cross-sectional views of a display panel according to an embodiment of the inventive concept.

### DETAILED DESCRIPTION

In the present disclosure, when an element (or a region, a layer, a portion, and the like) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents. The term “and/or,” includes all combinations of one or more of which associated components may define.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the present invention. The terms of a singular form may include plural forms unless the context clearly indicates otherwise.

In addition, terms such as “below,” “lower,” “above,” “upper,” and the like are used to describe the relationship of the components shown in the drawings. The terms are used as a relative concept and are described with reference to the direction indicated in the drawings.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

Hereinafter, a display panel according to an embodiment of the inventive concept and a manufacturing method thereof will be described with reference to the accompanying drawings.

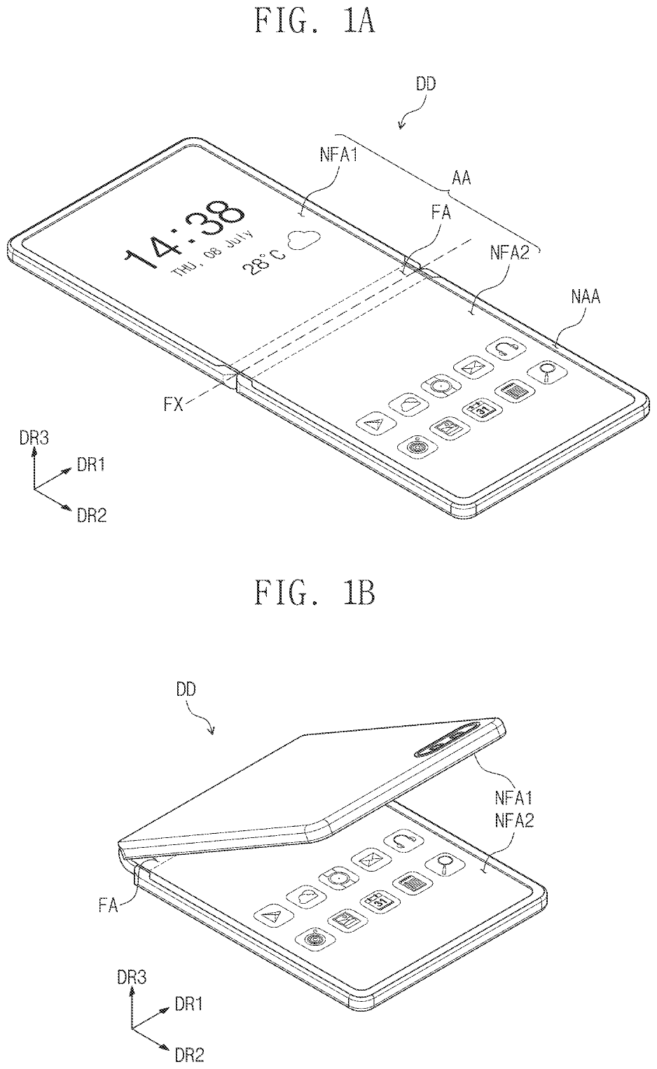

FIG. 1A is a perspective view of an unfolded state of a display device according to an embodiment of the inventive concept. FIG. 1B is a perspective view of a folded state of a display device according to an embodiment of the inventive concept.

Referring to FIG. 1A and FIG. 1B, a display device DD according to an embodiment of the inventive concept may be a device activated and operated according to an electrical signal. For example, the display device DD may be a mobile phone, a tablet computer, a car navigation system unit, a game console, or a wearable device, but is not limited thereto. In FIG. 1A, the display device DD is exemplarily illustrated as a mobile phone.

The display device DD may display an image and sense an external input through an active area AA. When the display device DD is in an unfolded (spread-out) state, the active area AA may include a plane defined by a first direction DR1 and a second direction DR2. A thickness direction of the display device DD may be defined as a third direction DR3, which is perpendicular to each of the first direction DR1 and the second direction DR2. Therefore, a front surface (or an upper surface) and a rear surface (or a lower surface) of members constituting the display device DD may be defined on the basis of the third direction DR3.

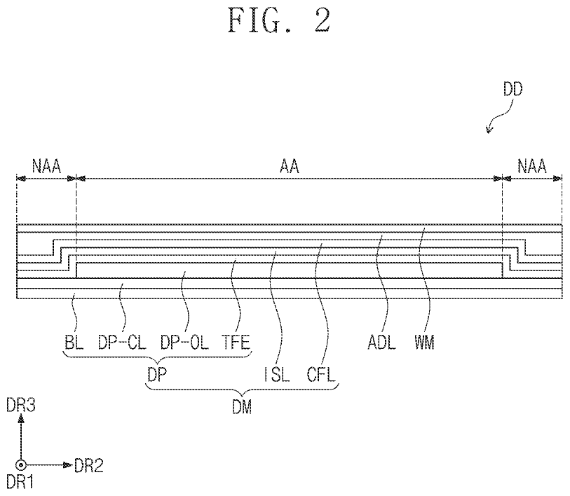

A peripheral area NAA may surround at least a portion of the active area AA. The peripheral area NAA may be a region defined by a bezel pattern either printed on a window WM (see FIG. 2), or provided in a tape form. The bezel pattern may include a predetermined color.

FIG. 1A exemplarily illustrates a peripheral area NAA surrounding four side surfaces of the active area AA, but the embodiment of the inventive concept is not limited thereto, and the peripheral area NAA may not be disposed on at least one side surface of the active area AA, or the peripheral area NAA may be omitted.

The display device DD according to the inventive concept may include a folding region FA and non-folding regions NFA1 and NFA2 spaced apart along the second direction DR2 with the folding region FA interposed therebetween. The folding region FA may be folded based on a virtual folding axis FX extending along the first direction DR1.

When the display device DD is folded, the folding may be done such that a first non-folding region NFA1 and a second non-folding region NFA2 face each other. Therefore, in a completely folded state, the active area AA may not be exposed to the outside. This type of folding may be referred to as “in-folding.” However, this is only exemplary, and the operation of the display device DD is not limited thereto.

For example, in an embodiment of the inventive concept, the display device DD may be folded such that the first non-folding region NFA1 and the second non-folding region NFA2 face away from each other. In this state, the active area AA is exposed to the outside even though the display device DD is folded. This type of folding may be referred to as “out-folding.”

The display device DD may be capable of performing either one of the in-folding operation or the out-folding operation. Alternatively, the display device DD may be built to perform both the in-folding operation and the out-folding operation. In this case, the same region of the display device DD, for example, the folding region FA may be in-folded and out-folded. Alternatively, some portions of the display device DD may be in-folded, and the other regions thereof may be out-folded.

In FIG. 1A and FIG. 1B, one folding region FA and two non-folding regions NFA1 and NFA2 are exemplarily illustrated, but the number of folding regions and the number of non-folding regions are not limited thereto. For example, the display device DD may include a plurality of non-folding regions, and a plurality of folding regions disposed between non-folding regions adjacent to each other.

In FIG. 1A and FIG. 1B, the folding axis FX is exemplarily illustrated as being parallel to a short axis of the display device DD extended in the first direction DR1, but the embodiment of the inventive concept is not limited thereto. For example, the folding axis FX may extend along a direction parallel to a long axis of the display device DD extended in the second direction DR2. In this case, the first non-folding region NFA1, the folding region FA, and the second non-folding region NFA2 may be sequentially arranged along the first direction DR1.

The appearance of the display device DD may be defined by the coupling of a case and the window WM (see FIG. 2). The case may be provided in plurality according to the number of non-folding regions, and may further include a hinge structure connecting the cases and overlapping a folding region to facilitate folding of the display device.

The display device DD may sense an external input applied from the outside. The external input may include various forms of input provided from the outside of the display device DD. For example, the external input may include a contact by an object such as a user's hand or finger, an external input applied in close proximity or adjacent to the display device DD at a predetermined distance (e.g., hovering). Also, the external input may have various forms, such as force, pressure, temperature, light, and the like.

FIG. 2 is a cross-sectional view of a display device according to an embodiment of the inventive concept.

Referring to FIG. 2, the display device DD may include the window WM, and a display module DM. The display module DM may include a display panel DP, an input sensing layer ISL, and a filter layer CFL. The window WM and the display module DM may be coupled to each other through an adhesive layer ADL disposed between the window WM and the display module DM. The adhesive layer ADL may include at least one of an optical clear adhesive, an optically clear adhesive resin, or a pressure sensitive adhesive (PSA).

A front surface of the window WM defines the active area AA of the display device DD. The window WM may include an optically transparent insulation material. For example, the window WM may include glass or plastic. The window WM may have a multi-layered structure or a single-layered structure. For example, the window WM may include a plurality of plastic films coupled using an adhesive, or a glass substrate and a plastic film coupled using an adhesive.

The display panel DP may be a component which substantially generates an image. The display panel DP may be a light emitting-type display panel, and for example, the display panel DP may be an organic light emitting display panel, an organic-inorganic light emitting display panel, a quantum-dot display panel, a micro-LED display panel, or a nano-LED display panel.

The display panel DP may include a base layer BL, a circuit layer DP-CL, an element layer DP-OL, and an encapsulation layer TFE.

The base layer BL may be a base layer on which remaining components of the display panel DP are disposed. The base layer BL may be composed of a flexible material.

The circuit layer DP-CL is disposed on the base layer BL. The circuit layer DP-CL includes at least one insulation layer and a circuit element. The insulation layer includes at least one inorganic layer and at least one organic layer. The circuit element may include a pixel driving circuit and the like included in each of a plurality of pixels for displaying an image. The element layer DP-OL may include a light emitting element connected to the circuit layer DP-CL.

The encapsulation layer TFE encapsulates the element layer DP-OL. The encapsulation layer TFE may include at least one organic layer and inorganic layers for encapsulating the organic layer. The inorganic layer includes an inorganic material, and may protect the element layer DP-OL from moisture/oxygen.

The inorganic layer may include a silicon nitride layer, a silicon oxynitride layer, a silicon oxide layer, a titanium oxide layer, an aluminum oxide layer, or the like, but is not particularly limited thereto. The organic layer includes an organic material, and may protect the element layer DP-OL from foreign substances such as dust particles. The organic layer may include an acrylic organic material, but is not particularly limited thereto.

The input sensing layer ISL may be disposed on the display panel DP. The input sensing layer ISL may sense an external input applied through the window WM. The external input may be a user input. The user input may include various forms of external inputs, such as contact, gesture, or proximity of a part of a user's body, light, heat, a pen, a pressure, or the like.

The input sensing layer ISL may be formed on the display panel DP through a continuous process. In this case, the input sensing layer ISL may be described as being directly disposed on the display panel DP. Being ‘directly disposed’ may mean that a third element is not disposed between the input sensing layer ISL and the display panel DP. That is, a separate adhesive member may not be disposed between the input sensing layer ISL and the display panel DP. Alternatively, the input sensing layer ISL and the display panel DP may be coupled to each other through an adhesive member. The adhesive member may include a typical adhesive or pressure-sensitive adhesive.

The filter layer CFL may be disposed on the input sensing layer ISL. The filter layer CFL may include a reflection prevention layer which reduces the reflectance of external light incident from the outside of the display device DD. However, the embodiment of the inventive concept is not limited thereto, and the filter layer CFL may include a color filter capable of selectively transmitting light corresponding to light provided from the display panel DP.

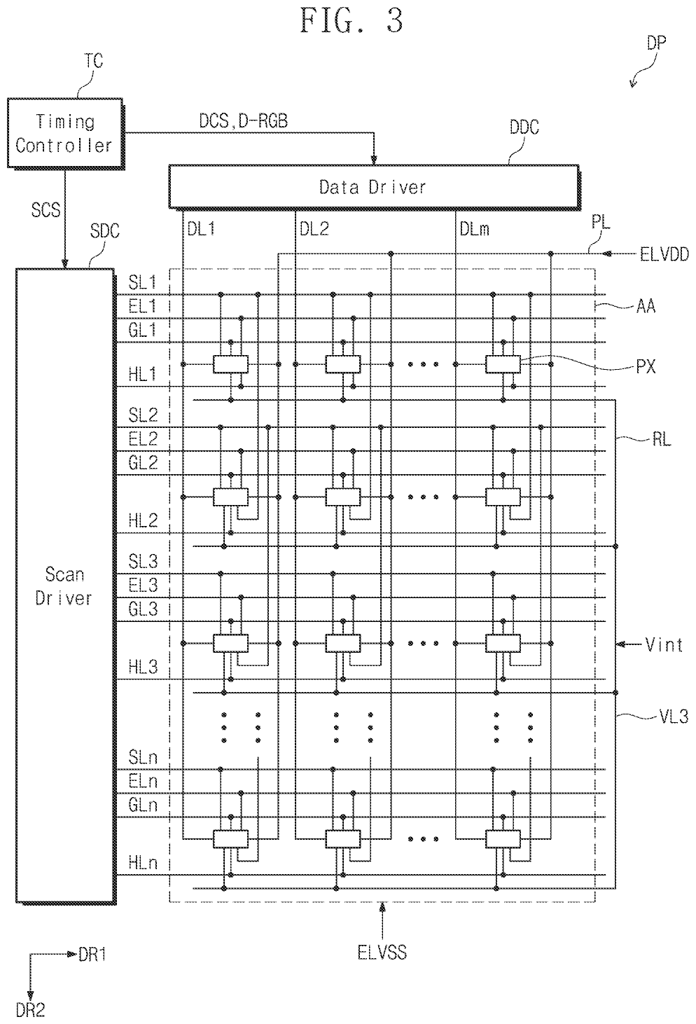

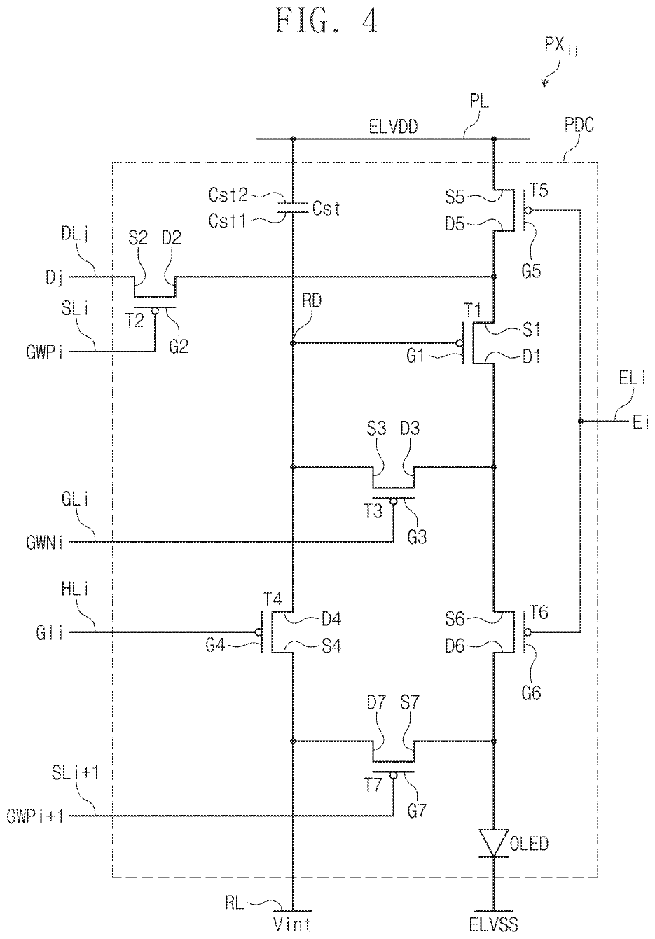

FIG. 3 is a block diagram of a display device according to an embodiment of the inventive concept.

Referring to FIG. 3, the display panel DP may include a timing controller TC, a scan driving circuit SDC, a data driving circuit DDC, and pixels PX overlapping the active area AA. In the present embodiment, the display panel DP will be described as an organic light emitting display panel, among the different types of light emitting-type display panels.

The timing controller TC receives input image signals, and converts a data format of the input image signals to match interface specifications of the scan driving circuit SDC to generate image data D-RGB. The timing control unit TC outputs the image data D-RGB and various control signals DCS and SCS.

The scan driving circuit SDC receives a scan control signal SCS from the timing controller TC. The scan control signal SCS may include a vertical start signal for starting the operation of the scan driving circuit SDC, a clock signal for determining the output timing of signals, and the like. The scan driving circuit SDC generates a plurality of scan signals, and sequentially outputs the plurality of scan signals to corresponding signal lines (SL1 to SLn, and GL1 to GLn). Also, the scan driver SDC generates a plurality of light emission control signals in response to the scan control signal SCS, and outputs the plurality of light emission control signals to corresponding signal lines EL1 to ELn.

In FIG. 3, a plurality of scan signals and a plurality of light emission control signals are illustrated as being output from one scan driving circuit SDC, but the embodiment of the inventive concept is not limited thereto. In an embodiment of the inventive concept, a plurality of scan driving circuits may divide, generate, and then output scan signals, and may divide, generate, and then output a plurality of light emission control signals. In addition, in an embodiment of the inventive concept, a driving circuit for generating and outputting a plurality of scan signals and a driving circuit for generating and outputting a plurality of light emission control signals may be different from each other.

The data driving circuit DDC receives a data control signal DCS and the image data D-RGB from the timing control unit TC. The data driving circuit DDC converts the image data D-RGB into data signals, and then outputs the data signals to a plurality of data lines DLI to DLm to be described later. The data signals are analog voltages corresponding to a gray scale value of the image data D-RGB.

The display panel DP includes scan lines SL1 to SLn of a first group, scan lines GL1 to GLn of a second group, scan lines HL1 to HLn of a third group, light emission lines EL1 to ELn, data lines DLI to DLm, a first voltage line PL, a second voltage line RL, and a plurality of pixels PX. The scan lines of the first group SL1 to SLn, the scan lines of the second group GL1 to GLn, the scan lines of the third group HL1 to HLn, and the light emission lines ELI to ELn are extended in the first direction DR1, and arranged in the second direction DR2 crossing the first direction DR1.

The plurality of data lines DLI to the DLm cross the scan lines of the first group SL1 to SLn, the scan lines of the second group GL1 to GLn, the scan lines of the third group HL1 to HLn, and the light emission lines EL1 to ELn while being insulated therefrom. Each of the plurality of pixels PX is connected to corresponding signal lines. Depending on the configuration of a driving circuit of the pixels PX, the connection relationship between the pixels PX and the signal lines may be changed.

The first voltage line PLI receives a first power voltage ELVDD. The second voltage line RL receives an initialization voltage Vint. The initialization voltage Vint has a lower level than the first power voltage ELVDD. A second power voltage ELVSS is applied to a light emitting element OLED (see FIG. 4). The second power voltage ELVSS has a lower level than the first power voltage ELVDD.

According to the inventive concept, “conductive patterns” described in the claims may correspond to at least one of scan lines, data lines, or power lines.

The plurality of pixels PX may include a plurality of groups which generate light of different colors from each other. For example, the pixels may include red pixels which generate red color light, green pixels which generate green color light, and blue pixels which generate blue color light. A light emitting element of a red pixel, a light emitting element of a green pixel, and a light emitting element of a blue pixel may include light emitting layers of different materials.

A pixel circuit PDC (see FIG. 4) included in each of the pixels PX may include a plurality of transistors, a capacitor electrically connected to the transistors, and the above-described conductive patterns. At least one of the scan driving circuit SDC and the data driving circuit DDC may include a plurality of transistors formed by the same process as a process of forming the pixel circuit PDC (see FIG. 4).

By performing a photolithography process a plurality of times, the scan lines, the plurality of pixels PX, the scan driving circuit SDC, and the data driving circuit DDC may be formed on the base layer BL (see FIG. 2). By performing a deposition process or a coating process a plurality of times, a plurality of insulation layers may be formed on the base layer BL (see FIG. 2). The plurality of insulation layers may be a thin film disposed to correspond to the plurality of pixels PX, and some of the plurality of insulation layers may include an insulation pattern overlapping a particular conductive pattern. The insulation layers include an organic layer and/or an inorganic layer.

FIG. 4 is an equivalent circuit diagram of a pixel according to an embodiment of the inventive concept.

FIG. 4 exemplarily illustrates a pixel PXij connected to an i-th scan line SLi of the scan lines SL1 to SLn of the first group, and connected to a j-th data line DLj of the plurality of data lines DLI to DLm.

In the present embodiment, the pixel circuit PDC may include first to seventh transistors T1 to T7, a capacitor Cst, and the above-described conductive patterns. In the present embodiment, the first transistor T1, the second transistor T2, and the fifth transistor T5 to the seventh transistor T7 are described as P-type transistors, and the third transistor T3 and the fourth transistor T4 are described as N-type transistors. However, the embodiment of the inventive concept is not limited thereto, and the first to seventh transistors T1 to T7 may be implemented as either P-type transistors or N-type transistors. Also, in an embodiment of the inventive concept, at least one of the first to seventh transistors T1 to T7 may be omitted.

In the present embodiment, the first transistor T1 may be a driving transistor, and the second transistor T2 may be a switching transistor. The capacitor Cst is connected between the first voltage line PL receiving the first power voltage ELVDD and a reference node RD. The capacitor Cst includes a first electrode Cst1 connected to the reference node RD and a second electrode Cst2 connected to the first voltage line PL.

The first transistor T1 is connected between the first voltage line PL and one electrode of the light emitting element OLED. A source S1 of the first transistor T1 is electrically connected to the first voltage line PL. Between the source S1 of the first transistor T1 and the first voltage line PL, another transistor may be disposed or omitted.

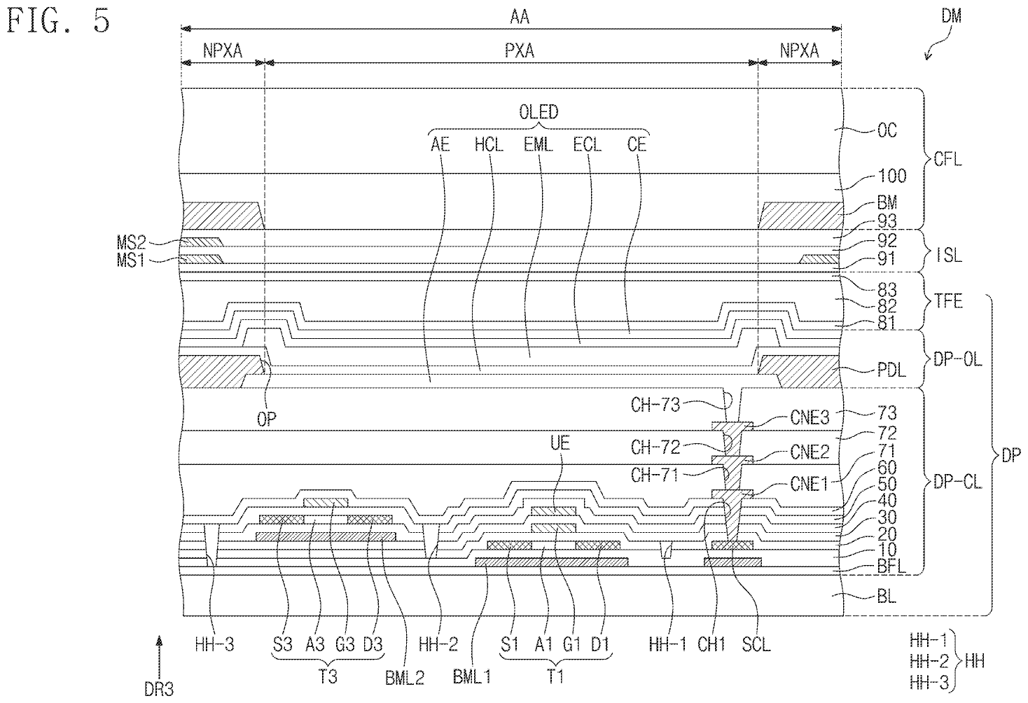

A drain D1 of the first transistor T1 is electrically connected to a first electrode AE of the light emitting element OLED. Between the drain D1 of the first transistor T1 and the first electrode AE (see FIG. 5) of the light emitting element OLED, another transistor (e.g., T6) may be disposed or omitted. A gate G1 of the first transistor T1 is electrically connected to the reference node RD.

The second transistor T2 is connected between the j-th data line DLj and the source S1 of the first transistor T1. A source S2 of the second transistor T2 is electrically connected to the j-th data line DLj, and a drain D2 of the second transistor T2 is electrically connected to the source S1 of the first transistor T1. In the present embodiment, a gate G2 of the second transistor T2 may be electrically connected to the i-th scan line SLi of the first group.

The third transistor T3 is connected between the reference node RD and the drain D1 of the first transistor T1. A drain D3 of the third transistor T3 is electrically connected to the drain D1 of the first transistor T1, and a source S3 of the third transistor T3 is electrically connected to the reference node RD. In the present embodiment, a gate G3 of the third transistor T3 may be electrically connected to an i-th scan line GLi of the second group.

The fourth transistor T4 is connected between the reference node RD and the second voltage line RL. A drain D4 of the fourth transistor T4 is electrically connected to the reference node RD, and a source S4 of the fourth transistor T4 is electrically connected to the second voltage line RL. In the present embodiment, a gate G4 of the fourth transistor T4 may be electrically connected to an i-th scan line HLi of the third group.

The fifth transistor T5 is connected between the first voltage line PL and the source S1 of the first transistor T1. A source S5 of the fifth transistor T5 is electrically connected to the first voltage line VL1, and a drain D5 of the fifth transistor T5 is electrically connected to the source S1 of the first transistor T1. A gate G5 of the fifth transistor T5 may be electrically connected to an i-th light emission line ELi.

The sixth transistor T6 is connected between the drain D1 of the first transistor T1 and the light emitting element OLED. A source S6 of the sixth transistor T6 is electrically connected to the drain D1 of the first transistor T1, and a drain D6 of the sixth transistor T6 is electrically connected to the first electrode AE (see FIG. 5) of the light emitting element OLED. A gate G6 of the sixth transistor T6 may be electrically connected to the i-th light emission line ELi.

The seventh transistor T7 is connected between the drain D6 of the sixth transistor T6 and the second voltage line RL. A source S7 of the seventh transistor T7 is electrically connected to the drain D6 of the sixth transistor T6, and a drain D7 of the seventh transistor T7 is electrically connected to the second voltage line RL. A gate G7 of the seventh transistor T7 may be electrically connected to an i+1-th scan line SLi+1 of the first group.

FIG. 5 is a cross-sectional view of a display module according to an embodiment of the inventive concept.

The display module DM may include a display panel DP, an input sensing layer ISL, and a color filter layer CFL. The display panel DP may include a base layer BL, a circuit layer DP-CL, an element layer DP-OL, and an encapsulation layer TFE.

The display panel DP may further include functional layers, such as a reflection prevention layer, a refractive index control layer, and the like. The circuit layer DP-CL includes at least a plurality of insulation layers and the pixel circuit PDC (see FIG. 4). Hereinafter, the insulation layers may include an organic layer and/or an inorganic layer.

The base layer BL may include a synthetic resin film. A synthetic resin layer may include a thermosetting resin. Particularly, the synthetic resin layer may be a polyimide-based resin layer, and the material thereof is not particularly limited. The synthetic resin layer may include at least any one of an acrylic resin, a methacrylic resin, polyisoprene, a vinyl-based resin, an epoxy-based resin, a urethane-based resin, a cellulose-based resin, a siloxane-based resin, a polyamide-based resin, or a perylene-based resin. In addition, the base layer may include a glass substrate, a metal substrate, an organic/inorganic composite substrate, or the like.

The base layer BL may be provided in a form in which organic layers and inorganic layers are alternately stacked. For example, the base layer BL may be provided having a structure in which a first organic layer including polyimide, a first inorganic layer disposed on the first organic layer, a second organic layer including polyimide and disposed on the first inorganic layer, and a second inorganic layer disposed on the second organic layer are stacked, but is not limited to any one embodiment.

The circuit layer DP-CL may include a plurality of insulation layers BFL, a first inorganic layer 10, a second inorganic layer 20, a third inoganic layer 30, a fourth inorganic layer 40, a fifth inorganic layer 50, a sixth inoganic layer 60, a first organic layer 71, a second organic layer 72, and a third organic layer 73, and conductive patterns included in transistors. Some of all of the inorganic layers 10, 20, 30, 40, 50, 60, and organic layers 71, 72, and 73 may herein be collectively referred to as an “insulation layer” due to their electrically insulative property.

An insulation layer, a semiconductor layer, and a conductive layer may be formed on the circuit layer DP-CL by coating, deposition, or the like. Thereafter, the insulation layer, the semiconductor layer, and the conductive layer may be selectively patterned by photolithography. In this manner, a semiconductor pattern, a conductive pattern, a signal line, and the like are formed.

The circuit layer DP-CL may include the plurality of insulation layers BFL, 10, 20, 30, 40, 50, 60, 71, 72, and 73, electrodes included in the capacitor Cst (see FIG. 4), electrodes included in the transistors T1 to T7 (see FIG. 4), and the above-described conductive patterns. In the present specification, a buffer layer BFL in contact with the base layer BL may be defined as a “lower inorganic layer.”

The lower inorganic layer BFL may be in contact with the base layer BL. The lower inorganic layer BFL may include an inorganic material. For example, the lower inorganic layer BFL may include at least one of aluminum oxide, titanium oxide, silicon oxide, silicon nitride, silicon oxynitride, zirconium oxide, or hafnium oxide. The lower inorganic layer BFL may be formed of multiple layers. The lower inorganic layer BFL may reduce surface energy of the base layer BL such that the pixel PX is stably formed on the base layer BL. For example, the lower inorganic layer BFL may be a buffer layer.

A first lower conductive layer BML1 may be disposed on the lower inorganic layer BFL.

The lower conductive layer BML1 may overlap a semiconductor pattern of the first transistor T1. When the lower inorganic layer BFL is omitted, the lower conductive layer BML1 may be directly disposed on the base layer BL. The lower conductive layer BML1 may include molybdenum. For example, the lower conductive layer BML1 may be a light blocking pattern.

The lower conductive layer BML1 may perform a shielding function. The lower conductive layer BML1 may prevent an electric potential due to a polarization phenomenon between insulation layers disposed on the lower conductive layer BML1 from affecting the first to seventh transistors T1 to T7.

The first inorganic layer 10 covers the lower conductive layer BML1 and is disposed on the lower inorganic layer BFL. The first inorganic layer 10 may include an inorganic material. For example, the first inorganic layer 10 may include at least one of aluminum oxide, titanium oxide, silicon oxide, silicon nitride, silicon oxynitride, zirconium oxide, or hafnium oxide. The first inorganic layer 10 may be formed of multiple layers. The first inorganic layer 10 may be an insulation layer.

The semiconductor pattern of the first transistor T1 is disposed on the first inorganic layer 10. The semiconductor pattern may include a silicon semiconductor. The semiconductor pattern may include polysilicon. However, the embodiment of the inventive concept is not limited thereto, and the semiconductor pattern may include amorphous silicon.

The source S1, an active region A1, and the drain D1 of the first transistor T1 are formed from a semiconductor pattern. The source S1 and the drain D1 of the first transistor T1 are formed spaced apart from each other with the active region A1 interposed therebetween.

FIG. 5 illustrates only a portion of the semiconductor pattern, and the semiconductor pattern may be further disposed in another region of the pixel PXij (see FIG. 4). The semiconductor pattern has different electrical properties depending on whether the semiconductor pattern is doped or not. The semiconductor pattern may include a doped region and a non-doped region. The doped region may be doped with an N-type dopant or a P-type dopant. A P-type transistor includes a doped region doped with the P-type dopant.

A connection signal line SCL is disposed on the first inorganic layer 10. The connection signal line SCL may be connected to the sixth transistor T6 (see FIG. 4) on a plane.

The second inorganic layer 20 covers the semiconductor pattern and the connection signal line SCL and is disposed on the first inorganic layer 10. The second inorganic layer 20 may include at least one of aluminum oxide, titanium oxide, silicon oxide, silicon nitride, silicon oxynitride, zirconium oxide, or hafnium oxide.

The gate G1 of the first transistor T1 is disposed on the second inorganic layer 20. The gate G1 may be a portion of a metal pattern. The gate G1 of the first transistor T1 overlaps the active region A1 of the first transistor T1. In a process of doping the semiconductor pattern, the gate G1 of the first transistor T1 is like a mask.

The third inorganic layer 30 covers the gate G1 and is disposed on the second inorganic layer 20. The third inorganic layer 30 may include at least one of aluminum oxide, titanium oxide, silicon oxide, silicon nitride, silicon oxynitride, zirconium oxide, or hafnium oxide.

An upper electrode UE may be disposed on the third inorganic layer 30. The upper electrode UE may overlap the gate G1. The upper electrode UE may be a portion of a metal pattern or a portion of a doped semiconductor pattern. A portion of the gate G1 and the upper electrode UE overlapping the same may define the capacitor Cst (see FIG. 4). In an embodiment, the upper electrode UE may be omitted.

A second lower conductive layer BML2 may be disposed on the third inorganic layer 30. The second lower conductive layer BML2 may overlap a semiconductor pattern of the third transistor T3. The second lower conductive layer BML2 may include molybdenum. For example, the second lower conductive layer BML2 may be a light blocking pattern. According to an embodiment, the second lower conductive layer BML2 may be omitted.

FIG. 5 illustrates that the third inorganic layer 30 is disposed in the entire region of the active area AA, but the embodiment of the inventive concept is not limited thereto, and the third inorganic layer 30 may be replaced with an insulation pattern. At this time, the upper electrode UE is disposed on the insulation pattern. The upper electrode UE may serve as a mask which forms an insulation pattern from the third inorganic layer 30.

According to an embodiment, the first electrode Cst1 (see FIG. 4) and the second electrode Cst2 (see FIG. 4) of the capacitor Cst (see FIG. 4) may be formed through the same process as the process of forming the gate G1 and the upper electrode UE. The first electrode Cst1 (see FIG. 4) may be disposed on the second insulation layer 20. The first electrode Cst1 (see FIG. 4) may be electrically connected to the gate G1. The first electrode Cst1 (see FIG. 4) may be have a shape of a single body with the gate G1.

The fourth inorganic layer 40 covers the upper electrode UE and the second light blocking pattern BML2 and is disposed on the third inorganic layer 30. The fourth inorganic layer 40 may include at least one of aluminum oxide, titanium oxide, silicon oxide, silicon nitride, silicon oxynitride, zirconium oxide, or hafnium oxide.

Sources S2, S5, S6, and S7 and drains D2, D5, D6, and D7 of the second, fifth, sixth, and seventh transistors T2, T5, T6, and T7 described with reference to FIG. 4 may be formed by the same process as the process of forming the source S1 and the drain D1 of the first transistor T1, and gates G2, G5, G6, and G7 of the second, fifth, sixth, and seventh transistors T2, T5, T6, and T7 may be formed by the same process as the process of forming the gate G1 of the first transistor T1. Patterns formed by the same process may be disposed on the same layer.

The semiconductor pattern of the third transistor T3 is disposed on the fourth inorganic layer 40. The semiconductor pattern may include a metal oxide. An oxide semiconductor may include a crystalline or amorphous oxide semiconductor. According to an embodiment, the semiconductor pattern may include a silicon semiconductor. For example, the silicon semiconductor may include amorphous silicon, polycrystalline silicon, and the like. For example, the semiconductor pattern may include a low-temperature polycrystalline silicon (LTPS).

For example, the oxide semiconductor may include any one of an indium-tin oxide (ITO), an indium-gallium-zinc oxide (IGZO), a zinc oxide (ZnO), an indium-zinc oxide (IZnO), a zinc-indium oxide (ZIO), an indium oxide (InO), a titanium oxide (TiO), an indium-zinc-tin oxide (IZTO), and a zinc-tin oxide (ZTO).

The source S3, an active region A3, and the drain D3 of the third transistor T3 are formed from a semiconductor pattern. The source S3 and the drain D3 include a metal reduced from a metal oxide semiconductor. The source S3 and the drain D3 have a predetermined thickness from an upper surface of the semiconductor pattern, and may include a metal layer including the reduced metal.

The fifth inorganic layer 50 covers the semiconductor pattern of the third transistor T3 and is disposed on the second inorganic layer 40. In the present embodiment, the fifth inorganic layer 50 may include a silicon oxide layer and a silicon nitride layer. The fifth inorganic layer 50 may include a plurality of alternately stacked silicon oxide layers and silicon nitride layers.

The gate G3 of the third transistor T3 is disposed on the fifth inorganic layer 50. The gate G3 may be a portion of a metal pattern. The gate G3 of the third transistor T3 overlaps the active region A3 of the third transistor T3.

FIG. 5 illustrates that the fifth inorganic layer 50 is disposed in the entire region of the active area AA, but the embodiment of the inventive concept is not limited thereto, and the fifth inorganic layer 50 may be replaced with an insulation pattern. The gate G3 of the third transistor T3 is disposed on the insulation pattern. In the present embodiment, the gate G3 may have the same shape as that of the insulation pattern on a plane.

The sixth inorganic layer 60 covers the gate G3 and is disposed on the fifth inorganic layer 50. In the present embodiment, the sixth inorganic layer 60 may include a silicon oxide layer and a silicon nitride layer. The sixth inorganic layer 60 may include a plurality of silicon oxide layers and silicon nitride layers alternately stacked.

According to an embodiment, the source S4 and the drain D4 of the fourth transistor T4 (see FIG. 4) may be formed through the same process as the process of forming the source S3 and the drain D3 of the third transistor T3, and the gate G3 of the fourth transistor T4 (see FIG. 4) may be formed through the same process as the process of forming the gate G3 of the third transistor T3.

At least one insulation layer may be further disposed on the sixth insulation layer 60. As in the present embodiment, the first organic layer 71, the second organic layer 72, and the third organic layer 73 may be disposed on the sixth inorganic layer 60. The first organic layer 71, to the second organic layer 72, and the third organic layer 73 may include an organic material. For example, the first, second, and third organic layers 71, 72, 73 may include a polyimide-based resin. However, the embodiment of the inventive concept is not limited thereto, and the organic layers 71, 72, 73 may include at least one of an acrylic resin, a methacrylic resin, polyisoprene, a vinyl-based resin, an epoxy-based resin, a urethane-based resin, a cellulose-based resin, a siloxane-based resin, a polyamide-based resin, or a perylene-based resin.

A first connection electrode CNE1 may be disposed on the sixth insulation layer 60. The first connection electrode CNE1 may be connected to the connection signal line SCL through a first contact-hole CHI extending through the first to sixth insulation layers 10 to 60. The first connection electrode CNE1 according to an embodiment may be connected to conductive patterns disposed on the same layer as the layer on which the semiconductor pattern of the first transistor T1 is disposed, and is not limited to any one embodiment.

The first organic layer 71 covers the first connection electrode CNE1 and is disposed on the sixth inorganic layer 60.

A second connection electrode CNE2 may be disposed on the first organic layer 71. The second connection electrode CNE2 is connected to the first connection electrode CNE1 through a second contact-hole CH-71 extending through the first organic layer 71.

The second organic layer 72 covers the second connection electrode CNE2 and is disposed on the first organic layer 71.

A third connection electrode CNE3 may be disposed on the second organic layer 72. The third connection electrode CNE3 is connected to the second connection electrode CNE2 through a third contact-hole CH-72 extending through the second organic layer 72.

The third organic layer 73 covers the third connection electrode CNE3 and is disposed on the second organic layer 72. In the display module DM according to an embodiment, the third connection electrode CNE3 and the third organic layer 73 may be omitted. At this time, the first electrode AE of the light emitting element OLED may be connected to the second connection electrode CNE2 through a fourth contact-hole CH-73 of the second organic layer 72, but is not limited to any one embodiment.

Components included in the light emitting element OLED may be disposed on the third organic layer 73. The light emitting device OLED may include the first electrode AE, a hole control layer HCL, a light emitting layer EML, an electron control layer ECL, and a second electrode CE. The pixel definition film PDL is disposed on the third organic layer 73. The pixel definition film PDL may have an opening OP defined thereon which exposes at least a portion of the first electrode AE. In the present embodiment, the pixel definition film PDL has a predetermined color, and may include a light absorbing material. For example, the pixel definition film PDL may have a black color.

The first to seventh transistors T1 to T7 (see FIG. 4) may constitute one pixel circuit PDC (see FIG. 4), and the pixel circuit PDC (see FIG. 4) and the light emitting element OLED may be connected to constitute one pixel PXij (see FIG. 4).

The opening OP of the pixel definition film PDL may define a light emitting region PXA. For example, a plurality of pixels PXij (see FIG. 4) may be disposed by a predetermined rule on a plane of the display panel DP. A region in which the plurality of pixels PXij are disposed may be defined as the active area AA (see FIG. 1A), and the active area AA may include a plurality of light emitting regions and a non-light emitting region NPXA adjacent to the light emitting regions. The non-light emitting region NPXA may surround the light emitting region PXA.

The first electrode AE is disposed on the third organic layer 73. The first electrode AE is connected to the third connection electrode CNE3 through a fourth contact-hole CH-73 extending through the third organic layer 73.

The hole control layer HCL disposed on the first electrode AE. The hole control layer HCL may be commonly disposed in the light emitting region PXA and the non-light emitting region NPXA. A common layer such as the hole control layer HCL and the electron control layer ECL may be commonly formed in the plurality of pixels PXij. The hole control layer HCL may include a hole transport layer and a hole injection layer.

The light emitting layer EML is disposed on the hole control layer HCL. The light emitting layer EML may overlap the opening OP. The light emitting layer EML may be divided and formed in each of the plurality of pixels PXij (see FIG. 4).

Although a patterned light emitting layer EML is exemplarily illustrated in the present embodiment, the light emitting layer EML may be commonly disposed in the plurality of pixels PXij. At this time, the light emitting layer EML may generate white light or blue light. In addition, the light emitting layer EML may have a multi-layered structure.

The electron control layer ECL is disposed on the light emitting layer EML. The electron control layer ECL may include an electron transport layer and an electron injection layer. The second electrode CE is disposed on the electron control layer ECL. The electron control layer ECL and the second electrode CE are commonly disposed in the plurality of pixels PXij (see FIG. 4).

The encapsulation layer TFE is disposed on the second electrode CE. The encapsulation layer TFE is commonly disposed in the plurality of pixels PXij (see FIG. 4). In the present embodiment, the encapsulation layer TFE directly covers the second electrode CE. The encapsulation layer TFE may include a first thin-film inorganic layer 81, a thin film organic layer 82, and a second thin-film inorganic layer 83. However, the embodiment of the inventive concept is not limited thereto, and the encapsulation layer TFE may further include a plurality of inorganic layers and a plurality of organic layers.

The first thin-film inorganic layer 81 may be in contact with the second electrode CE. The first thin-film inorganic layer 81 may prevent external moisture or oxygen from penetrating into the light emitting layer EML. For example, the first thin-film inorganic layer 81 may include a silicon nitride, a silicon oxide, or a compound thereof. The first thin-film inorganic layer 81 may be formed through a deposition process.

The thin film organic layer 82 may be disposed on the first thin-film inorganic layer 81 to be in contact with the first thin-film inorganic layer 81. The thin film organic layer 82 may provide a flat surface on the first thin-film inorganic layer 81. Curves formed on an upper surface of the first thin-film inorganic layer 81 or particles and the like present on the first thin-film inorganic layer 81 are covered by the thin film organic layer 82, so that the surface state of the upper surface of the first thin-film inorganic layer 81 may be prevented from affecting components formed on the thin film organic layer 82. The thin film organic layer 82 may include an organic material, and may be formed though a solution process, such as spin coating, slit coating, and ink jet processes.

The second thin-film inorganic layer 83 is disposed on the thin film organic layer 82 and covers the thin film organic layer 82. The second thin-film inorganic layer 83 may be stably formed on a relatively flat surface than being disposed on the first thin-film inorganic layer 81. The second thin-film inorganic layer 83 prevents moisture, oxygen, or the like from entering the light emitting layer EML. The second thin-film inorganic layer 83 may include a silicon nitride, a silicon oxide, or a compound thereof. The second thin-film inorganic layer 83 may be formed through a deposition process.

The input sensing layer ISL may be directly disposed on the encapsulation layer TFE. The input sensing layer ISL may include a plurality of conductive patterns MS1 and MS2, and sensing insulation layers. The sensing insulation layers may include a first sensing insulation layer 91, a second sensing insulation layer 92, and a third sensing insulation layer 93.

The first sensing insulation layer 91 is disposed on the encapsulation layer TFE. First conductive patterns MS1 are disposed on the first sensing insulation layer 91, and may be covered by the second sensing insulation layer 92. Second conductive patterns MS2 are disposed on the second sensing insulation layer 92, and may be covered by the third sensing insulation layer 93.

Each of the conductive patterns MS1 and MS2 has conductivity. Each of the conductive patterns MS1 and MS2 may be provided as a single layer, or a plurality of layers, but is not limited to any one embodiment. At least one conductive pattern of the conductive patterns MS1 and MS2 according to the inventive concept may be provided as a mesh line on a plane.

Mesh lines constituting the conductive patterns MS1 and MS2 may overlap the pixel definition film PDL on a plane. Therefore, even when the input sensing layer ISL is directly formed on the display panel DP, light formed in the pixels PXij (see FIG. 4) of the display panel DP may be provided to a user without interference of the input sensing layer ISL.

The color filter layer CFL may include a color filter 100, a black matrix BM, and an overcoat layer OC.

The color filter 100 may include a polymer photosensitive resin and a pigment or dye. For example, a color filter 100 overlapping a light emitting layer EML that provides blue light may include a blue pigment or dye, a color filter 100 overlapping a light emitting layer EML that provides green light may include a green pigment or dye, and a color filter 100 overlapping a light emitting layer EML that provides red light may include a red pigment or dye.

However, the embodiment of the inventive concept is not limited thereto, and the color filter 100 overlapping the light emitting layer EML that provides blue light may not include a pigment or dye. In this case, the color filter 100 may be transparent, and the color filter 100 may be formed of a transparent photosensitive resin.

The black matrix BM may be disposed between color filters that transmit light of different peak wavelength from each other. The black matrix BM is a pattern having a black color, and may be a grid-type matrix. The black matrix BM may include a black coloring agent. The black coloring agent may include a black dye and a black pigment. The black coloring agent may include carbon black, a metal such as chromium, or an oxide thereof.

The overcoat layer OC may be disposed on the color filter 100 and the black matrix BM. The overcoat layer OC may be a layer that covers the uneven surface and irregularities generated during forming of the color filter 100 and the black matrix BM, and provides a flat surface. That is, the overcoat layer OC may be a planarization layer. The window WM described with reference to FIG. 2 may be coupled to the overcoat layer OC by the adhesive layer ADL.

The circuit layer DP-CL according to the present embodiment may have an opening from which at least some of the first to sixth inorganic layers 10 to 60 (“inorganic layers” in the claims) are removed. In the present embodiment, an embodiment in which first to third openings HH-1, HH-2, and HH-3 are defined is illustratively described. As illustrated in the drawing, the first to third openings HH-1, HH-2, and HH-3 may each be formed, but not limited thereto, by removing some of the inorganic layers 10 to 60 disposed below the first organic layer 71. Alternatively, the first, second, and third openings HH-1, HH-2, HH-3 may be formed by forming an opening that extends from the sixth inorganic layer 60 to the first inorganic layer 10 disposed on the lower inorganic layer BFL. In addition, as illustrated in the drawing, the first to third openings HH-1, HH-2, and HH-3 may each be formed, but not limited thereto, by removing adjacently-positioned inorganic layers, or may be formed by selectively removing parts of the inorganic layers on a cross-section while being formed in adjacent inorganic layers. The openings HH-1, HH-2, HH-3 may be characterized by the absence of the material that forms the walls of the openings.

According to an embodiment, the first to third openings HH-1, HH-2, and HH-3 may not be under the contact-holes CH-71, CH-72, and CH-73 in which the first to third connection electrodes CNE1, CNE2, and CNE3 are disposed.

For example, on a plane, the first opening HH-1 may be positioned between the first transistor T1 and the contact-holes CH-71, CH-72, and CH-73. The second opening HH-2 may be positioned between the first transistor T1 and the third transistor T3. The third opening HH-3 may be spaced apart, on a plane, from the first transistor T1 with the third transistor T3 interposed therebetween.

As illustrated in the drawing, each of the first opening HH-1, the second opening HH-2, and the third opening HH-3 may not overlap some components of the first transistor T1 or the second transistor T2 on a plane, but is not limited to what is illustrated in the drawing, and a portion of each of the first opening HH-1, the second opening HH-2, and the third opening HH-3 may overlap some components of the first transistor T1 or the second transistor T2 on a plane, and is not limited to any one embodiment.

The first to third openings HH-1, HH-2, and HH-3 may allow at least one of the first to sixth inorganic layers 10 to 60 overlapping the pixel circuit PDC to be discontinuous on a plane. In other words, the first to third openings HH-1, HH-2, and HH-3 may eliminate continuity on a plane by removing some regions of at least one layer of the first to sixth inorganic layers 10 to 60 on a plane.

According to an embodiment of the inventive concept, by removing some regions of at least one layer of the first to sixth inorganic layers 10 to 60, it is possible to disperse an external force applied to the inorganic layers during folding-unfolding processes. Accordingly, it is possible to prevent cracks from being generated in the inorganic layers, and to prevent the spread of generated cracks.

Meanwhile, due to the first to third openings HH-1, HH-2, and HH-3 according to an embodiment of the inventive concept, any one of the first to sixth inorganic layers 10 to 60 overlapping the pixel circuit PDC may have a shape of being floated on a plane, as will be described later.

For example, FIG. 5 illustrates a cross-section of a portion corresponding to the first transistor T1 and the third transistor T3 among the first to seventh transistors T1 to T7 described with reference to FIG. 4. However, without being limited thereto, the first transistor and the third transistor illustrated in FIG. 5 may be two transistors different from each other among the aforementioned first to seventh transistors, and are not limited to any one embodiment.

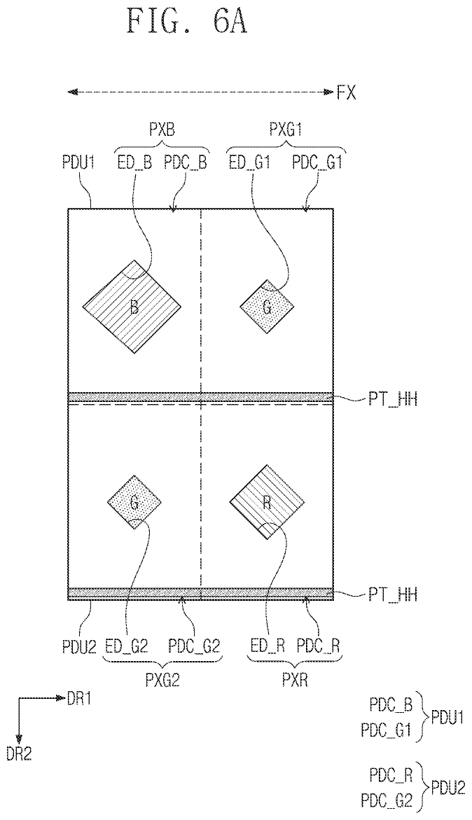

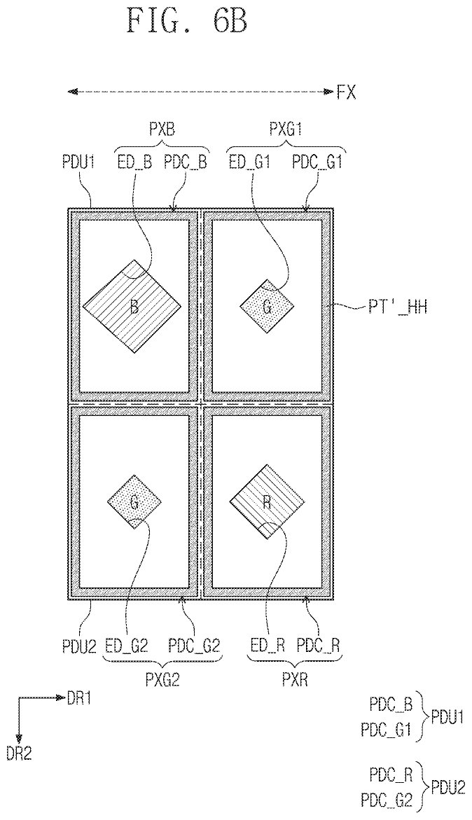

FIG. 6A and FIG. 6B are plan views of adjacent pixels according to an embodiment of the inventive concept. Specifically, FIG. 6A and FIG. 6B show various embodiments of the shape of an opening on a plane.

FIG. 6A and FIG. 6B illustrate four pixels PXB, PXG1, PXG2, and PXR arranged in two rows and two columns. For ease of description, in FIG. 6A and FIG. 6B, regarding a light emitting element and a pixel circuit which constitute each of the pixels PXB, PXG1, PXG2, and PXR, a region in which light is emitted is referred to as a light emitting element, and a region in which a pixel circuit illustrated in FIG. 4 is disposed is referred to as a pixel circuit. The shape of the light emitting element may substantially correspond to the shape of the opening OP of the pixel definition film PDL described with reference to FIG. 5, and the shape of the region in which the pixel circuit is disposed is illustrated as a quadrangular shape.

Referring to FIG. 6A and FIG. 6B, the four pixels PXB, PXG1, PXG2, and PXR include a 1-1 pixel PXB and a 1-2 pixels PXG1 arranged along the first direction DR1 and constituting the first row, and include a 2-1 pixel PXG2 and a 2-2 pixel PXR arranged along the first direction DR1 and constituting the second row. The 1-1 pixel PXB includes a first pixel circuit PDC_B and a 1-1 light emitting element ED_B connected to the first pixel circuit PDC_B. The 1-2 pixel PXG1 includes a second pixel circuit PDC_G1 and a 1-2 light emitting element ED_G1 connected to the second pixel circuit PDC_G1.

In the present embodiment, the first pixel circuit PDC_B and the second pixel circuit PDC_G1 adjacent thereto in the first direction DR1 may be defined as a first pixel circuit unit PDU1.

The 2-1 pixel PXG2 may include a 2-1 pixel circuit PDC_G2 and a 2-1 light emitting element ED_G2 connected to the 2-1 pixel circuit PDC_G2. The 2-2 pixel PXR may include a 2-2 pixel circuit PDC_R and a 2-2 light emitting element ED_R connected to the 2-2 pixel circuit PDC_R.

In the present embodiment, the 2-1 pixel circuit PDC_G2 and the 2-2 pixel circuit PDC_R adjacent thereto in the first direction DR1 may be defined as a second pixel circuit unit PDU2.

According to an embodiment, the 1-1 pixel PXB may emit blue light, the 1-2 pixel PXG1 and the 2-1 pixel PXG2 may each emit green light, and the 2-2 pixel PXR may emit red light. The peak wavelength of each of the green light generated by the 1-2 pixel PXG1 and the 2-1 pixel PXG2 may be the same or different. However, this is exemplarily illustrated, and three or more pixel circuits may be disposed in one pixel circuit unit, and the inventive concept is not limited to any one embodiment.

When the display device DD (see FIG. 1) is folded or unfolded around the folding axis FX, an external force or stress may be applied to each layer constituting the display device DD. The amount of stress caused by the folding operation may increase with distance from the folding axis FX on a display surface. That is, referring to FIG. 6A and FIG. 6B, when the folding axis FX is defined parallel to the first direction DR1, among the regions of the display panel DP (see FIG. 5), stress applied thereto may increase as the distance from the folding axis FX along the second direction DR2 increases.

For ease of description, in FIG. 6A and FIG. 6B, the shape of an opening HH (see FIG. 5) extended along one direction on a plane is defined as an opening pattern PT_HH and PT′ HH.

According to the inventive concept, on a plane, the opening pattern PT_HH may have the shape of a bar extending along a direction parallel to the folding axis FX, as depicted in FIG. 6A. The opening pattern PT_HH may be provided in plurality and arranged spaced apart along the second direction DR2. The plurality of opening patterns PT_HH may be arranged spaced apart along a direction perpendicular to the folding axis FX and formed in an inorganic layer. The plurality of opening patterns PT_HH may block continuity along the second direction DR2 of an inorganic layer formed in the entire region of a display panel.

For example, the inorganic layer illustrated in FIG. 6A may be overlap all of the four pixel circuits PDC_B, PDC_R, PDC_G1, and PDC_G2, but the continuity of an inorganic layer between the first pixel circuit unit PDU1 and the second pixel circuit unit PDU2 may be blocked by the plurality of opening patterns PT_HH. Accordingly, a region in which spatial separation occurs may be created between an inorganic layer forming the first pixel circuit unit PDU1 and an inorganic layer forming the second pixel circuit unit PDU2. In addition, as illustrated in FIG. 6B, an area in which spatial separation occurs may also be created even within the inorganic layer forming the first pixel circuit unit PDU1, and this is also the case with the second pixel circuit unit PDU2.

The opening patterns PT_HH divide a single inorganic layer into a plurality of portions along the second direction DR2, so that the continuity in the second direction DR2 extending from the folding axis FX to an end (or an end of the inorganic layer) of the display panel DP (see FIG. 5) may be blocked. Accordingly, it is possible to alleviate the concentration of stress applied to the inorganic layer, and prevent the spread of cracks caused from the folding stress. Therefore, the reliability of the display panel (DP, see FIG. 5) according to the folding stress may improve.

Referring to FIG. 6B, the opening pattern PT′_HH may have a closed curve or frame shape on a plane. The opening pattern PT′ HH may have a quadrangular shape surrounding one pixel, and the opening pattern PT′_HH may be provided in plurality and arranged in a matrix along the first direction and the second direction. Alternatively, the opening pattern PT′_HH may have a lattice shape with a shape of a single body.

Specifically, the opening pattern PT′_HH according to an embodiment of the inventive concept may surround each of corresponding pixels PXB, PXG1, PXG2, and PXR. The opening pattern PT′_HH surrounding each of the pixels PXB, PXG1, PXG2, and PXR may have a symmetrical shape along the first direction DR1 and the second direction DR2.

The opening pattern PT′_HH may allow the first to sixth inorganic layers 10 to 60 (see FIG. 5) overlapping each of the pixels PXB, PXG1, PXG2, and PXR to be discontinuous on a plane. Therefore, the first to sixth inorganic layers 10 to 60 (see FIG. 5) disposed in each of the pixels PXB, PXG1, PXG2, and PXR may be defined as being in a floated state. The floated state may be defined as not only being electrically insulated but also being short-circuited in an island shape.

The opening pattern PT′_HH according to an embodiment of the inventive concept is provided to surround each of the corresponding pixels PXB, PXG1, PXG2, and PXR, and thus, may prevent cracks from being generated in the first to sixth inorganic layers 10 to 60 (see FIG. 5), and even when cracks are generated, it is possible to prevent the cracks from spreading to another inorganic layer along an inorganic layer. In addition, it is possible to prevent cracks generated in a region adjacent to one pixel from spreading to another pixel adjacent thereto.

The opening patterns PT′_HH according to an embodiment are illustrated as being spaced apart from each other, but adjacent opening patterns PT′_HH may be defined as one pattern, and are not limited to any one embodiment.

Unlike what is illustrated in the drawing, the opening patterns PT′_HH according to an embodiment of the inventive concept may surround the first pixel circuit unit PDU1 or the second pixel circuit unit PDU2, which corresponds thereto. Therefore, the opening pattern PT′ HH may define the boundary between the first pixel circuit units PDU1 which are adjacent in the first direction DR1, and the boundary between the second pixel circuit units PDU2 which are adjacent in the first direction DR1. Accordingly, since external impacts or cracks are prevented from spreading to the pixel circuit units PDU1 and PDU2, the display device DD (see FIG. 1) with improved durability may be provided.

FIG. 6A illustrates a case in which the opening pattern PT_HH extends in a direction parallel to the first direction DR1, and FIG. 6B illustrates a case in which the opening pattern PT′_HH extends in the first direction DR1 and in the second direction DR2. However, without being limited to what is illustrated in the drawings, the opening patterns PH_HH and PT′_HH may extend in a direction different from the first direction DR1 and the second direction DR2, and are not limited to any one embodiment.

Cross-sections of the opening patterns PH_HH and PT′ HH illustrated in FIG. 6A and FIG. 6B according to a direction intersecting the first direction DR1 and the second direction DR2 may correspond to the opening HH (see FIG. 5) illustrated in FIG. 5, and may be provided in various cross-sectional shapes without being limited to the shape of the opening illustrated in FIG. 5, and are not limited to one embodiment.

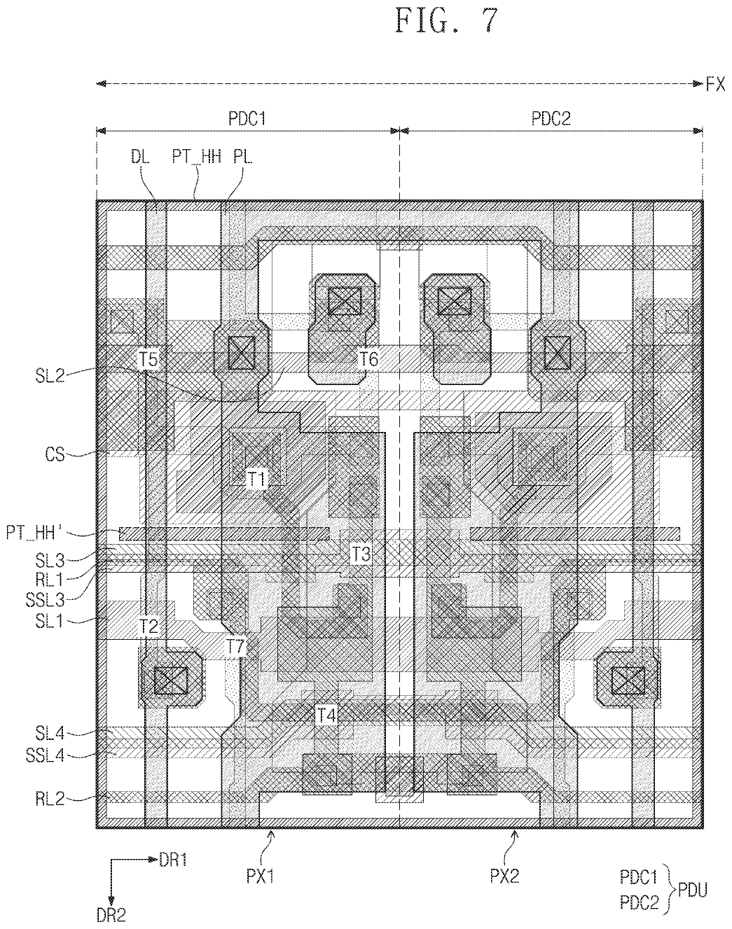

FIG. 7 is a plan view illustrating a portion of a circuit layer according to an embodiment of the inventive concept. In FIG. 7, for ease of description, in the circuit layer DP-CL (see FIG. 5), a region in which a first pixel circuit and a second pixel circuit adjacent in the first direction DR1 are disposed is exemplarily illustrated. Each of the first and second pixel circuits may include components corresponding to the pixel circuit PDC (see FIG. 4) illustrated in FIG. 4. Hereinafter, the inventive concept will be described with reference to FIG. 7.

Each of conductive patterns and semiconductor patterns included in each of pixel circuits PDC1 and PDC2 may have a structure of being repeatedly arranged by a predetermined rule. Hereinafter, for the convenience of explanation, reference numerals will be omitted for the same elements among elements disposed in each of the pixels PX1 and PX2. In addition, for the convenience of explanation, some layers corresponding to the first lower conductive layer BML1 (see FIG. 4) and the second lower conductive layer BML2 (see FIG. 5) are omitted and some corresponding layers are omitted from the illustration.

Referring to FIG. 7, a second scan line SL2, a first voltage line RL1, a third scan line SL3, a first scan line SL1, a fourth scan line SL4, and a second voltage line RL2 are arranged along the second direction DR2, and each thereof may overlap the two pixels PX1 and PX2 and be extended along the first direction DR1.

The first scan line SL1 may correspond to the i-th scan line SLi (see FIG. 4) of the first group of FIG. 4, and the second scan line SL2 may correspond to the i-th light emission line ELi (see FIG. 4) of FIG. 4. The third scan line SL3 may correspond to the i-th scan line GLi (see FIG. 4) of the second group of FIG. 4, and the fourth scan line SL4 may correspond to the i-th scan line HLi (see FIG. 4) of the third group of FIG. 4. Each of the first voltage line RL1 and the second voltage line RL2 may correspond to the second voltage line RL (see FIG. 4) of FIG. 4, and may receive the initialization voltage Vint. The data line DL may correspond to the j-th data line DLj (see FIG. 4) of FIG. 4, and the voltage line PL may correspond to the first voltage line PL (see FIG. 4).

The data line DL is extended along the second direction DR2. Different data lines DL may be respectively disposed in the first pixel circuit PDC1 and the second pixel circuit PDC2. The voltage line PL may be disposed spaced apart from the data line DL in the first direction DR1. The first pixel circuit PDC1 and the second pixel circuit PDC2 may be connected to a common voltage line PL.

The first transistor T1 may be formed between the second scan line SL2 and the third scan line SL3. The second transistor T2 may be formed at a position at which the first scan line SL1 and the data line DL intersect. The third transistor T3 and the fourth transistor T4 may be disposed at positions spaced apart in the second direction DR2. The fifth transistor T5 may be formed along the second scan line SL2 and the data line DL. The sixth transistor T6 may be disposed spaced apart from the fifth transistor T5 in the first direction DR1 along the second scan line SL2. The seventh transistor T7 may be disposed at a position spaced apart from the second transistor T2 in the first direction DR1 along the first scan line SL1.

The voltage line PL may overlap the first transistor T1, the third transistor T3, the fourth transistor T4, and the seventh transistor T7 on a plane.

A third sub-scan line SSL3 and a fourth sub-scan line SSL4 may respectively overlap the third scan line SL3 and the fourth scan line SLA, and may be connected through a contact-hole to reduce the resistance of the third scan line SL3 and the fourth scan line SLA.

Any one of the pixels PX1 and PX2 illustrated in FIG. 7 may correspond to at least one of the 1-1 pixel PXB, the 1-2 pixel PXG1, the 2-1 pixel PXG2, and the 2-2 pixel PXR described above with reference to FIG. 6, and is not limited to any one embodiment.

One pixel circuit unit PDU according to the inventive concept may be defined as including a first pixel circuit PDC1 and a second pixel circuit PDC2 disposed in two adjacent pixels PX1 and PX2. In the pixel circuit unit PDU according to the inventive concept, a first opening pattern PT-HH and a second opening pattern PT-HH′ may be defined. The first opening pattern PT-HH and the second opening pattern PT-HH′ may have different shapes from each other.

Specifically, the first opening pattern PT-HH according to an embodiment may surround one pixel circuit unit PDU and define the boundary with an adjacent pixel circuit unit. Therefore, the first opening pattern PT-HH may have a shape surrounding the first pixel circuit PDC1 and the second pixel circuit PDC 2. As a result, even when cracks are generated, it is possible to prevent the cracks from spreading to another inorganic layer along an inorganic layer. In addition, it is possible to prevent cracks generated in a region adjacent to one pixel from spreading to another pixel adjacent thereto.

The second aperture pattern PT_HH′ may be defined in a region overlapping the pixel circuit units PDU between the first opening pattern PT_HH. The second opening pattern PT_HH′ may be positioned between a pair of transistors among the first to seventh transistors T1 to T7. For example, the second opening pattern PT_HH′ may be positioned between the first transistor T1 and the third transistor T3. As a result, it is possible to prevent cracks generated in a region adjacent to one transistor from spreading to another transistor adjacent thereto. In addition, the second opening pattern PT_HH′ may extend in a direction parallel to the folding axis FX or in the first direction DR.

However, the second opening pattern PT_HH′ is not limited to the position described above, and may be positioned to be adjacent to or to overlap transistors other than the first transistor T1 and the third transistor T3, and may extend in a direction different from the direction parallel to the folding axis FX, and is not limited to any one embodiment.

As to be described below, the first opening pattern PT_HH and the second opening pattern PT_HH′ may be formed by removing at least some of the first to sixth inorganic layers 10 to 60 illustrated in FIG. 5. The first opening pattern PT_HH or the second aperture pattern PT_HH′ may be formed by the same process as the process of forming a gate or a conductive pattern. Therefore, it is possible to form an opening pattern using the same mask as the mask used for forming the gate or the conductive pattern.

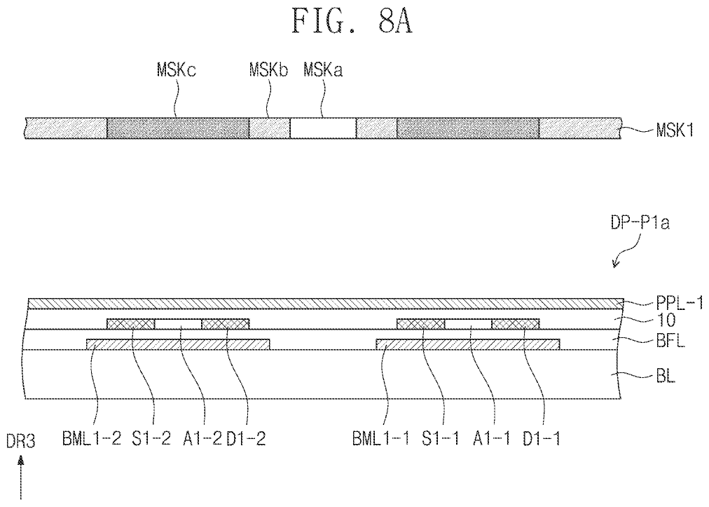

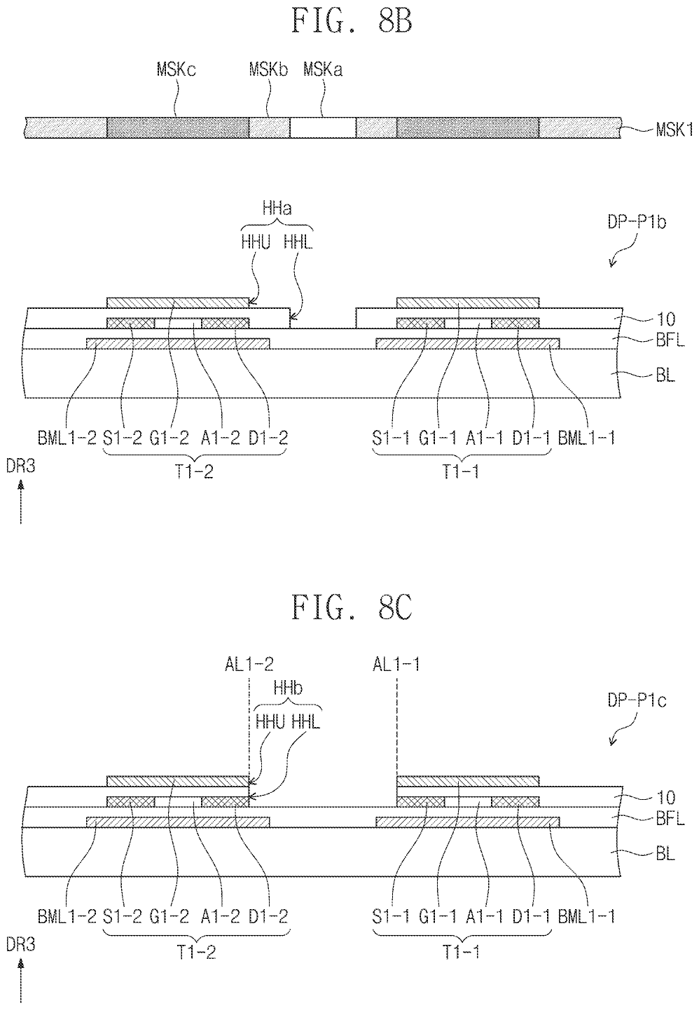

FIG. 8A to FIG. 8C are cross-sectional views of a preliminary display panel according to an embodiment of the inventive concept. Specifically, FIG. 8A is a cross-sectional view of a first preliminary display panel DP-P1a before an opening is formed in a first inorganic layer, FIG. 8B is a cross-sectional view of a second preliminary display panel DP-P1b after the opening is formed in the first inorganic layer, and FIG. 8C is a cross-sectional view of a third preliminary display panel DP-Plc after the opening is formed in the first inorganic layer.

The same reference numerals are given to the same components as the components described with reference to FIG. 1 and FIG. 7, and a detailed description thereof will be omitted.

In FIG. 8A, the first preliminary display panel DP-P1a before forming the display panel DP (see FIG. 5) is illustrated, and in FIG. 8B, the second preliminary display panel DP-P1b after performing a patterning process on some layers of the first preliminary display panel DP-P1a is illustrated.

Referring to FIG. 8A, the lower inorganic layer BFL may be disposed on the base layer BL of the first preliminary display panel DP-P1a, and the first inorganic layer 10 may be disposed on the lower inorganic layer BFL. A plurality of patterns may be formed on the lower inorganic layer BFL. As an example, the plurality of patterns may include a 1-1 source S1-1, a 1-1 active region A1-1, a 1-1 drain D1-1, a 1-2 source S1-2, a 1-2 active region A1-2, and a 1-2 drain D1-2.

The 1-1 source S1-1, the 1-1 active region A1-1, and the 1-1 drain D1-1 may be components formed in a semiconductor pattern of a 1-1 transistor T1-1 (see FIG. 8B) to be described below. In addition, the 1-2 source S1-2, the 1-2 active region A1-2, and the 1-2 drain D1-2 may be components formed in a semiconductor pattern of a 1-2 transistor T1-2 (see FIG. 8B) to be described below.

On the lower inorganic layer BFL, the first inorganic layer 10 may be disposed. A semiconductor pattern of the 1-1 transistor T1-1 (see FIG. 8B) and the 1-2 transistor T1-2 (see FIG. 8B) may be disposed between the lower inorganic layer BFL and the first inorganic layer 10.

On the first inorganic layer 10, a first preliminary pattern layer PPL-1 may be formed. The first preliminary pattern layer PPL-1 may include a conductive material, and may include, for example, a metal. The first preliminary pattern layer PPL-1 may be formed by depositing or coating a conductive material.

Referring to FIG. 8A and FIG. 8B, a 1-1 gate G1-1, a 1-2 gate G1-2, and an opening HHa may be formed through a patterning process using a first mask MSK1. Specifically, the first preliminary pattern layer PPL-1 of the first preliminary display panel DP-P1a may be patterned to include the 1-1 gate G1-1 and the 1-2 gate G1-2, and to form the second preliminary display panel DP-P1b having the opening HHa.

According to an embodiment of the inventive concept, the first mask MSK1 may be provided as a half-tone mask. The half-tone mask may include a plurality of mask regions having the same transmittance or different transmittances.

The first mask MSK1 may include a first mask region MSKa having a first transmittance, a second mask region MSKb having a second transmittance, and a third mask region MSKc having a third transmittance. The first transmittance may be greater than or equal to the second transmittance, and the second transmittance may be greater than or equal to the third transmittance. The magnitude relationship among the above-described first and third transmittances may vary depending on a transmission target, and is not limited to the position illustrated in the drawing.

The 1-1 gate G1-1 and the 1-2 gate G1-2 may be formed by the third mask region MSKc having the lowest transmittance of the three regions described above. In the first preliminary pattern layer PPL-1, a region corresponding to the third mask region MSKc remains without being etched, thereby forming the 1-1 gate G1-1 and the 1-2 gate G1-2.

In the first preliminary pattern layer PPL-1, a region corresponding to the first mask region MSKa and the second mask region MSKb may be removed by etching. The first preliminary pattern layer PPL-1 may be etched to expose the first insulation layer 10. A portion of the first preliminary pattern layer PPL-1 may be etched to form an upper opening HHU. As illustrated in the drawing, the inner surface of the upper opening HHU may correspond to one side surface of the 1-1 gate G1-1 and the 1-2 gate G1-2, but is not limited to any one embodiment.

A region corresponding to the first mask region MSKa having the highest transmittance may be further etched to form a lower opening HHL. In the first inorganic layer 10 exposed by removing the first preliminary pattern layer PPL-1, a region corresponding to the first mask region MSKa may be etched to expose the lower inorganic layer BFL. In the first inorganic layer 10, a region removed by the first mask region MSKa may form the lower opening HHL. That is, the shape of the lower opening HHL may correspond to the shape of the first mask region MSKa.

Through the above-described etching process, the 1-1 gate G1-1 and the 1-2 gate G1-2 may be formed in the same process as that of the upper opening HHU and the lower opening HHL. In addition, the 1-1 gate G1-1 and the 1-2 gate G1-2 may be simultaneously formed with the upper opening HHU, and are not limited to any one embodiment.

The opening HHa may include the upper opening HHU and the lower opening HHL. As described above, the inner surface of the upper opening HHU may be two side surfaces facing each other in the 1-1 gate G1-1 and the 1-2 gate G1-2. The opening HHa includes the upper opening HHU and the lower opening HHL, and thus may form a step due to the different dimensions of the upper opening HHU and the lower opening HHL. In the drawing, the lower opening HHL is illustrated as an opening formed by removing part of the first inorganic layer 10. However, in some embodiments, the lower opening HHL may be formed by also removing some of the lower inorganic layer BFL to be a “deeper” opening.

Referring to FIG. 8C, the second preliminary display panel DP-P1b (see FIG. 8B) illustrated in FIG. 8B may be formed as the third preliminary display panel DP-Plc of FIG. 8C through additional patterning. In the first inorganic layer 10 illustrated in FIG. 8B, a portion defining the lower opening HHL and protruding from the upper opening HHU may be etched by using the 1-1 gate G1-1 or the 1-2 gate G1-2 as a mask. Accordingly, the portion of the first inorganic layer 10 the lower opening HHL may be aligned with the upper opening HHU on a cross-section, and an opening HHb may be formed as an opening having an aligned side surface. Using the 1-1 gate G1-1 or the 1-2 gate G1-2 as a mask, the opening HHb may be formed as an opening having an aligned side surface without a separate additional mask. As illustrated in the drawing, the lower opening HHL and the upper opening HHU may be substantially aligned along a first alignment line AL1-1 and a second alignment line AL1-2, but are not limited thereto, and may be substantially aligned along a direction different from the third direction DR3, and are not limited to any one embodiment.

However, the embodiment of the inventive concept is not limited thereto, and in the first preliminary display panel DP-P1a (see FIG. 8A) illustrated in FIG. 8A, the third preliminary display panel DP-Plc illustrated in FIG. 8C may be formed through a different patterning process from FIG. 8B. As an example, in the mask MSK1 illustrated in FIG. 8A, the opening HHb as illustrated in FIG. 8C may be formed by allowing the transmittance of the first mask region MSKa and the transmittance of the second mask region MSKb to be the same, and is not limited to any one embodiment.

Either one of the 1-1 transistor T1-1 and the 1-2 transistor T1-2 may correspond to the first transistor T1 described above, and the other one of the 1-1 transistor T1-1 and the 1-2 transistor T1-2 may correspond to the second to seventh transistors T2 to T7, and is not limited to any one embodiment.

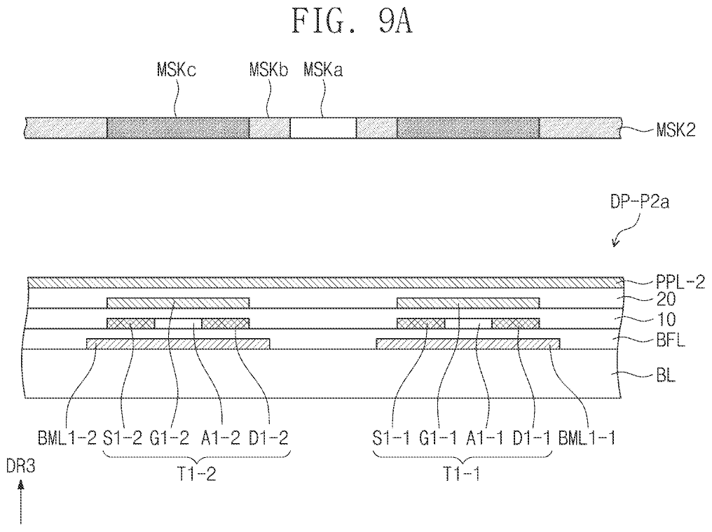

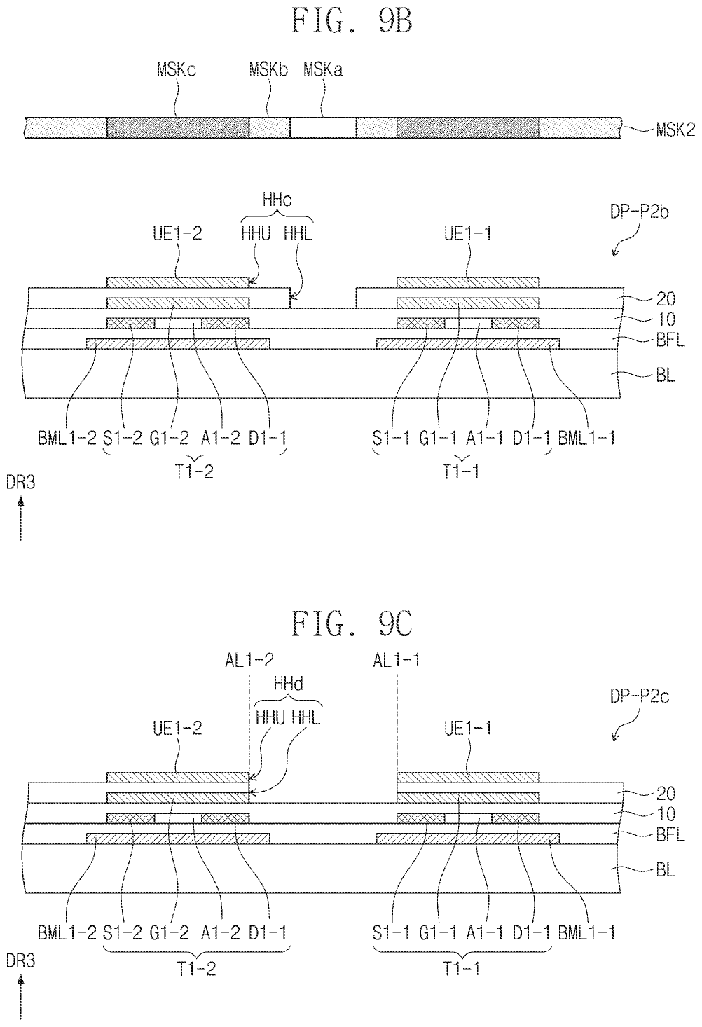

FIG. 9A to FIG. 9C are cross-sectional views of a preliminary display panel according to an embodiment of the inventive concept. Specifically, FIG. 9A is a cross-sectional view of a first preliminary display panel DP-P2a before an opening is formed in a second inorganic layer, FIG. 9B is a cross-sectional view of a second preliminary display panel DP-P2b after the opening is formed in the second inorganic layer, and FIG. 9C is a cross-sectional view of a third preliminary display panel DP-P2c after the opening is formed in the second inorganic layer.

Referring to FIG. 9A, a first inorganic layer 10 may be disposed on a lower inorganic layer BFL of the first preliminary display panel DP-P2a, and a second inorganic layer 20 may be disposed on the first inorganic layer 10.

A plurality of patterns may be formed on the lower inorganic layer BFL, and the plurality of patterns may be the semiconductor patterns described above with respect to FIG. 8A and FIG. 8B.

On the second inorganic layer 20, a second preliminary pattern layer PPL-2 may be formed. The second preliminary pattern layer PPL-2 may include a conductive material, and may include, for example, a metal. The second preliminary pattern layer PPL-2 may be formed by depositing or coating a conductive material.

Referring to FIG. 9A and FIG. 9B, a 1-1 upper electrode UE1-1, a 1-2 upper electrode UE1-2, and an opening HHc may be formed through a patterning process using a second mask MSK2. Specifically, the second preliminary pattern layer PPL-2 of the first preliminary display panel DP-P1a may be patterned to include the 1-1 upper electrode UE1-1 and the 1-2 upper electrode UE1-2, and to form the second preliminary display panel DP-P2b having the opening HHc.

According to an embodiment of the inventive concept, the second mask MSK2 may include a first mask region MSKa having a first transmittance, a second mask region MSKb having a second transmittance, and a third mask region MSKc having a third transmittance. The first transmittance may be greater than or equal to the second transmittance, and the second transmittance may be greater than or equal to the third transmittance. The magnitude relationship among the above-described first and third transmittances may vary depending on a transmission target, and is not limited to the position illustrated in the drawing.

The 1-1 upper electrode UE1-1 and the 1-2 upper electrode UE1-2 may be formed by the third mask region MSKc having the lowest transmittance. In the second preliminary pattern layer PPL-2, a region corresponding to the third mask region MSKc remains without being etched, thereby forming the 1-1 upper electrode UE1-1 and the 1-2 upper electrode UE1-2.

In the second preliminary pattern layer PPL-2, a region corresponding to the first mask region MSKa and the second mask region MSKb may be removed by etching. The second preliminary pattern layer PPL-2 may be etched to expose the second insulation layer 20. A portion of the second preliminary pattern layer PPL-2 may be etched to form an upper opening HHU. As illustrated in the drawing, the inner surface of the upper opening HHU may correspond to one side surface of the 1-1 upper electrode UE1-1 and the 1-2 upper electrode UE1-2, but is not limited to any one embodiment.

A region corresponding to the first mask region MSKa having the highest transmittance may be further etched to form a lower opening HHL. In the second inorganic layer 20 exposed by removing the second preliminary pattern layer PPL-2, a region corresponding to the first mask region MSKa may be etched to expose the first inorganic layer 10. In the second inorganic layer 20, a region removed by the first mask region MSKa may form the lower opening HHL. That is, the shape of the lower opening HHL may correspond to the shape of the first mask region MSKa.

Through the above-described etching process, the 1-1 upper electrode UE1-1 and the 1-2 upper electrode UE1-2 may be formed in the same process as that of the upper opening HHU and the lower opening HHL. In addition, the 1-1 upper electrode UE1-1 and the 1-2 upper electrode UE1-2 may be simultaneously formed with the upper opening HHU, and are not limited to any one embodiment.

The opening HHc may include the upper opening HHU and the lower opening HHL. As described above, the inner surface of the upper opening HHU may be two side surfaces facing each other in the 1-1 upper electrode UE1-1 and the 1-2 upper electrode UE1-2. The opening HHc includes the upper opening HHU and the lower opening HHL, which may form a step due to their different dimensions. In the drawing, the lower opening HHL is illustrated as an opening formed by removing the second inorganic layer 20. However, the lower opening HHL may be made “deeper” by also removing the first inorganic layer 10 and the lower inorganic layer BFL, depending on the embodiment.

Referring to FIG. 9C, the second preliminary display panel DP-P2b (see FIG. 9B) illustrated in FIG. 9B may be formed as the third preliminary display panel DP-P2c of FIG. 9C through additional patterning. In the embodiment illustrated in FIG. 9B, a portion of the second inorganic layer 20 defining the lower opening HHL that extends beyond the upper opening HHU may be etched by using the 1-1 upper electrode UE1-1 or the 1-2 upper electrode UE1-2 as a mask. Accordingly, the lower opening HHL may be aligned with the upper opening HHU on a cross-section, and an opening HHd may be formed as an opening having an aligned side surface. Using the 1-1 upper electrode UE1-1 or the 1-2 upper electrode UE1-2 as a mask, the opening HHd may be formed as an opening having an aligned side surface without a separate additional mask. As illustrated in the drawing, the edges of the lower opening HHL and the upper opening HHU may be substantially aligned along a first alignment line AL1-1 and a second alignment line AL1-2. However, this alignment is not a limitation, and the edges may be substantially aligned along a direction different from the third direction DR3, depending on the embodiment.

However, the embodiment of the inventive concept is not limited thereto, and in the first preliminary display panel DP-P2a (see FIG. 9A) illustrated in FIG. 9A, the third preliminary display panel DP-P2c illustrated in FIG. 9C may be formed through a different patterning process from FIG. 9B. For example, in the second mask MSK2 illustrated in FIG. 9A, the opening HHd as illustrated in FIG. 9C may be formed by allowing the transmittance of the first mask region MSKa and the transmittance of the second mask region MSKb to be the same, and is not limited to any one embodiment.

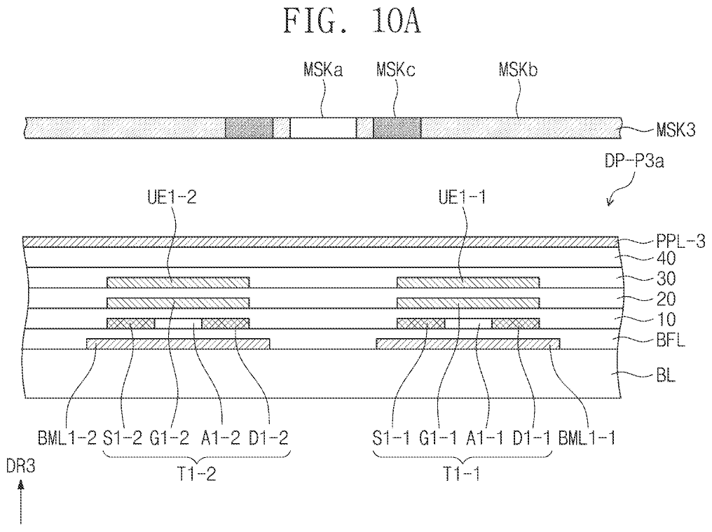

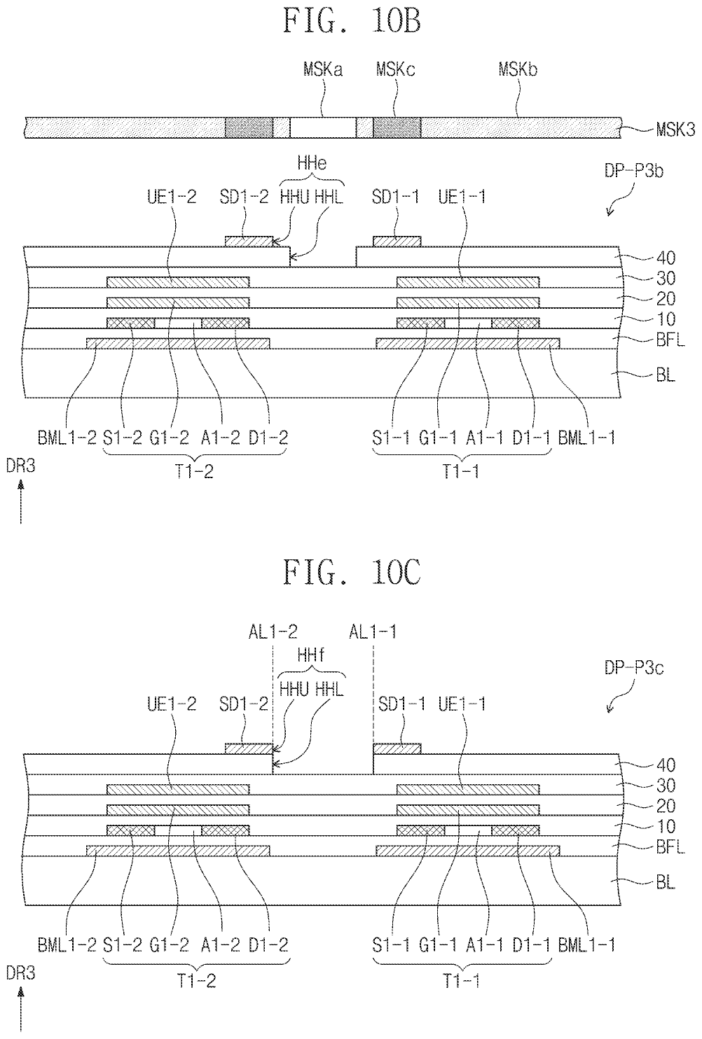

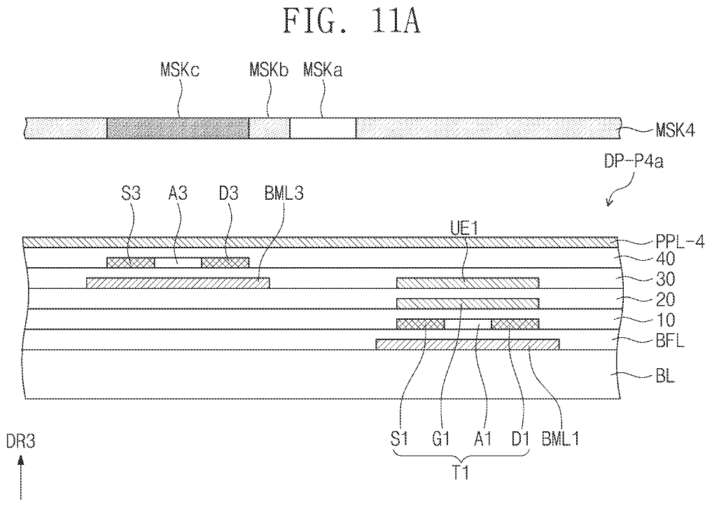

FIG. 10A and FIG. 10B are cross-sectional views of a preliminary display panel according to an embodiment of the inventive concept. Specifically, FIG. 10A is a cross-sectional view of a first preliminary display panel DP-P3a before an opening is formed in a fourth inorganic layer 40, FIG. 10B is a cross-sectional view of a second preliminary display panel DP-P3b after the opening is formed in the fourth inorganic layer 40, and FIG. 10C is a cross-sectional view of a third preliminary display panel DP-P3c after the opening is formed in the fourth inorganic layer 40.

Referring to FIG. 10A, a third inorganic layer 30 may be disposed on a second inorganic layer 20 of the first preliminary display panel DP-P3a, and a fourth inorganic layer 40 may be disposed on the third inorganic layer 30.

On the fourth inorganic layer 40, a third preliminary pattern layer PPL-3 may be formed. The third preliminary pattern layer PPL-3 may include a conductive material, and may include, for example, a metal. The third preliminary pattern layer PPL-3 may be formed by depositing or coating a conductive material.

Referring to FIG. 10A and FIG. 10B, a first conductive pattern SD1-1, a second conductive pattern SD1-2, and an opening HHe may be formed through a patterning process using a third mask MSK3. Specifically, the third preliminary pattern layer PPL-3 of the first preliminary display panel DP-P3a may be patterned to include the first conductive pattern SD1-1 and the second conductive pattern SD1-2, and to form the second preliminary display panel DP-P3b having the opening HHe.

According to an embodiment of the inventive concept, the third mask MSK3 may include a first mask region MSKa having a first transmittance, a second mask region MSKb having a second transmittance, and a third mask region MSKc having a third transmittance. The first transmittance may be greater than or equal to the second transmittance, and the second transmittance may be greater than or equal to the third transmittance. The magnitude relationship among the above-described first and third transmittances may vary depending on a transmission target, and is not limited to the position illustrated in the drawing.

The first conductive pattern SD1-1 and the second conductive pattern SD1-2 may be formed by the third mask region MSKc having the lowest transmittance. In the third preliminary pattern layer PPL-3, a region corresponding to the third mask region MSKc remains without being etched, thereby forming the first conductive pattern SD1-1 and the second conductive pattern SD1-2.

In the third preliminary pattern layer PPL-3, a region corresponding to the first mask region MSKa and the second mask region MSKb may be removed by etching. The third preliminary pattern layer PPL-3 may be etched to expose the third insulation layer 30. A portion of the third preliminary pattern layer PPL-3 may be etched to form an upper opening HHU. As illustrated in the drawing, the inner surface of the upper opening HHU may correspond to one side surface of the first conductive pattern SD1-1 and the second conductive pattern SD1-2, but is not limited to any one embodiment.

A region corresponding to the first mask region MSKa having the highest transmittance may be further etched to form a lower opening HHL. In the fourth inorganic layer 40 exposed by removing the third preliminary pattern layer PPL-3, a region corresponding to the first mask region MSKa may be etched to expose the third inorganic layer 30. In the fourth inorganic layer 40, a region removed by the first mask region MSKa may form the lower opening HHL. That is, the shape of the lower opening HHL may correspond to the shape of the first mask region MSKa.

Through the above-described etching process, the first conductive pattern SD1-1 and the second conductive pattern SD1-2 may be formed in the same process as that of the upper opening HHU and the lower opening HHL. In addition, the first conductive pattern SD1-1 and the second conductive pattern SD1-2 may be simultaneously formed with the upper opening HHU, and are not limited to any one embodiment.

The opening HHe may include the upper opening HHU and the lower opening HHL. As described above, the inner surface of the upper opening HHU may be two side surfaces facing each other in the first conductive pattern SD1-1 and the second conductive pattern SD1-2. The opening HHe includes the upper opening HHU and the lower opening HHL, and thus may have a step on a cross-section. In the drawing, the lower opening HHL is illustrated as an opening formed by removing part of the fourth inorganic layer 40, but the lower opening HHL may further extend into the third inorganic layer 30 in some embodiments.

Referring to FIG. 10C, the second preliminary display panel DP-P3b (see FIG. 10B) illustrated in FIG. 10B may be formed as the third preliminary display panel DP-P3c of FIG. 10C through additional patterning. In the fourth inorganic layer 40 illustrated in FIG. 10B, a portion defining the lower opening HHL and protruding from the upper opening HHU may be etched by using the first conductive pattern SD1-1 or the second conductive pattern SD1-2 as a mask. Accordingly, the edge of the lower opening HHL may be aligned with the edge of the upper opening HHU on a cross-section, and an opening HHf may be formed as an opening having a side surface without the uneven surface of a step. Using the first conductive pattern SD1-1 or the second conductive pattern SD1-2 as a mask, the opening HHf may be formed as an opening having an even side surface without a separate, additional mask. As illustrated in the drawing, the edges of the lower opening HHL and the upper opening HHU may be substantially aligned along a first alignment line AL1-1 and a second alignment line AL1-2. However, this alignment is not a limitation of the disclosure. In other embodiments, the upper opening HHU and the lower opening HHL may be substantially aligned along a direction different from the third direction DR3.

In the first preliminary display panel DP-P3a (see FIG. 10A) illustrated in FIG. 10A, the third preliminary display panel DP-P3c illustrated in FIG. 10C may be formed through a different patterning process from what is depicted in FIG. 10B. For example, in the third mask MSK3 illustrated in FIG. 10A, the opening HHf as illustrated in FIG. 10C may be formed by allowing the transmittance of the first mask region MSKa and the transmittance of the second mask region MSKb to be the same in some embodiments.

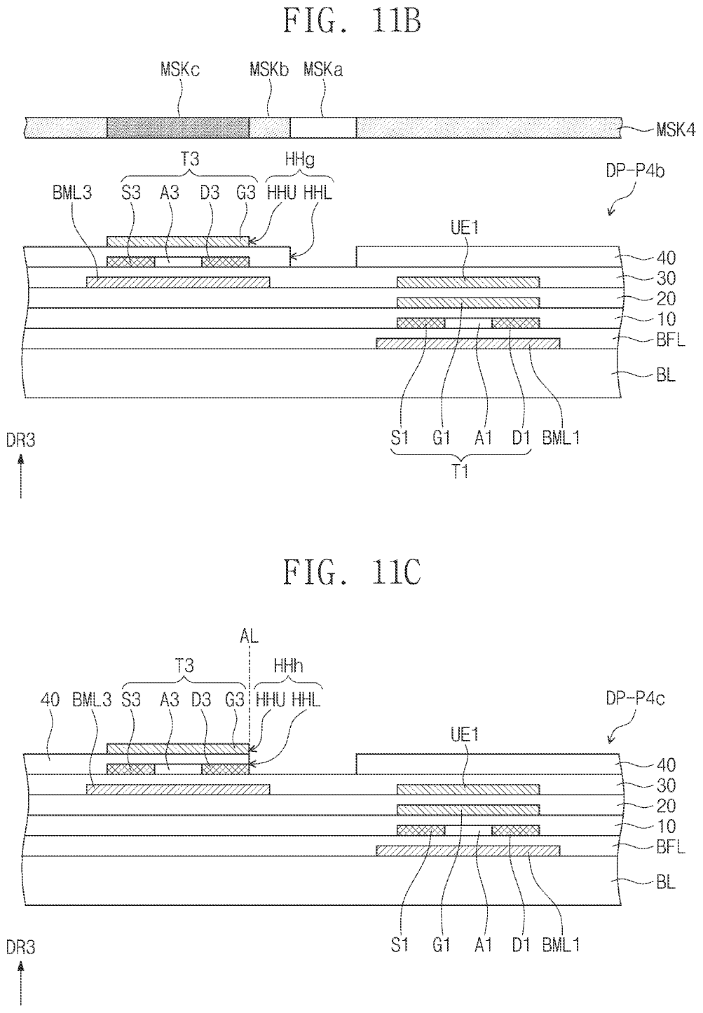

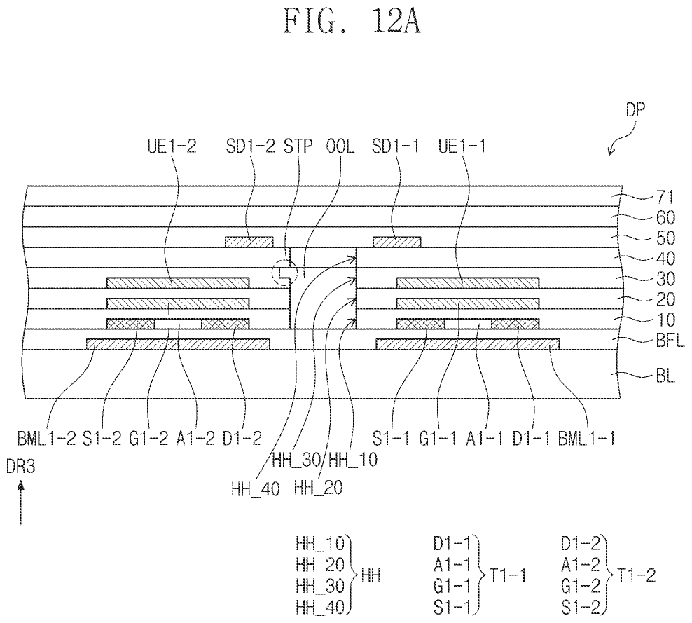

FIG. 11A and FIG. 11B are cross-sectional views of a preliminary display panel according to an embodiment of the inventive concept. Specifically, FIG. 11A is a cross-sectional view of a first preliminary display panel DP-P4a before an opening is formed in a fourth inorganic layer 40, FIG. 11B is a cross-sectional view of a second preliminary display panel DP-P4b after the opening is formed in the fourth inorganic layer 40, and FIG. 11C is a cross-sectional view of a third preliminary display panel DP-P4c after the opening is formed in the fourth inorganic layer 40.

Referring to FIG. 11A, a plurality of patterns may be formed on a lower inorganic layer BFL. The plurality of patterns comprises a first source S1, a first active region A1, and a first drain D1. The first source S1, the first active region A1, and the first drain D1 may be components formed in a semiconductor pattern of a first transistor T1.

On a first inorganic layer 10, a first gate G1 may be disposed, and on a second inorganic layer 20, a first upper electrode UE1 may be disposed. The first gate G1 may be a gate electrode of the first transistor.

On a third inorganic layer 30, a third source S3, a third active region A3, and a third drain D3 may be disposed. The third source S3, the third active region A3, and the third drain D3 may be components formed in a semiconductor pattern of a third transistor T3.

On a fourth inorganic layer 40, a fourth preliminary pattern layer PPL-4 may be formed. The fourth preliminary pattern layer PPL-4 may include a conductive material, and may include, for example, a metal. The fourth preliminary pattern layer PPL-4 may be formed by depositing or coating a conductive material.

Referring to FIG. 11A and FIG. 11B, a third gate G3, and an opening HHg may be formed through a patterning process using a fourth mask MSK4. Specifically, the fourth preliminary pattern layer PPL-4 of the first preliminary display panel DP-P4a may be patterned to include the third gate G3, and to form the second preliminary display panel DP-P4b having the opening HHg.

According to an embodiment of the inventive concept, the fourth mask MSK4 may include a first mask region MSKa having a first transmittance, a second mask region MSKb having a second transmittance, and a third mask region MSKc having a third transmittance. The first transmittance may be greater than or equal to the second transmittance, and the second transmittance may be greater than or equal to the third transmittance. The magnitude relationship among the above-described first and third transmittances may vary depending on a transmission target, and is not limited to the position illustrated in the drawing.

The third gate G3 may be formed by the third mask region MSKc having the lowest transmittance. In the fourth preliminary pattern layer PPL-4, a region corresponding to the third mask region MSKc remains without being etched, thereby forming the third gate G3.

In the fourth preliminary pattern layer PPL-4, a region corresponding to the first mask region MSKa and the second mask region MSKb may be removed by etching. The fourth preliminary pattern layer PPL-4 may be etched to expose the third insulation layer 30. A portion of the fourth preliminary pattern layer PPL-4 may be etched to form an upper opening HHU. As illustrated in the drawing, the inner surface of the upper opening HHU may correspond to one side surface of the third gate G3, but is not limited to any one embodiment.

A region corresponding to the first mask region MSKa having the highest transmittance may be further etched to form a lower opening HHL. In the fourth inorganic layer 40 exposed by removing the fourth preliminary pattern layer PPL-4, a region corresponding to the first mask region MSKa may be etched to expose the third inorganic layer 30. In the fourth inorganic layer 40, a region removed by the first mask region MSKa may form the lower opening HHL. That is, the shape of the lower opening HHL may correspond to the shape of the first mask region MSKa.

Through the above-described etching process the third gate G3 may be formed in the same process as that of the upper opening HHU and the lower opening HHL. In addition, the third gate G3 may be simultaneously formed with the upper opening HHU.

The opening HHg may include the upper opening HHU and the lower opening HHL. As described above, the inner surface of the upper opening HHU may be one side surface of the third gate G3. The opening HHg includes the upper opening HHU and the lower opening HHL, and the two openings HHU and HHL may form a step due to their difference in dimensions. In the drawing, the lower opening HHL is illustrated as an opening formed by removing part of the fourth inorganic layer 40. However, the lower opening HHL may be made deeper by also removing part of the third inorganic layer 30, and is not limited to any one embodiment.

Referring to FIG. 11C, the second preliminary display panel DP-P4b (see FIG. 11B) illustrated in FIG. 11B may be formed as the third preliminary display panel DP-P4c of FIG. 11C through additional patterning. In the fourth inorganic layer 40 illustrated in FIG. 11B, a portion defining the lower opening HHL and extending beyond the edge of the upper opening HHU may be etched by using the third gate G3 as a mask. Accordingly, the edge of the lower opening HHL may be aligned with the edge of the upper opening HHU, and an opening HHh may be formed with an even side surface free of a step. Using the third gate G3 as a mask, the opening HHh may be formed as an opening having an aligned side surface without a separate additional mask. As illustrated in the drawing, the lower opening HHL and the upper opening HHU may be substantially aligned along an alignment line AL. However, this alignment is not a limitation of the disclosure, and in some embodiments, the lower opening HHL and the upper opening HHU may be substantially aligned along a direction different from the third direction DR3.

In the first preliminary display panel DP-P4a (see FIG. 11A) illustrated in FIG. 11A, the third preliminary display panel DP-P4c illustrated in FIG. 11C may be formed through a different patterning process from FIG. 11B. For example, in the fourth mask MSK4 illustrated in FIG. 11A, the opening HHf as illustrated in FIG. 11C may be formed by allowing the transmittance of the first mask region MSKa and the transmittance of the second mask region MSKb to be the same.

A first transistor T1 may be the first transistor T1 (see FIG. 5) described with respect to FIG. 5, and a third transistor T3 may be the third transistor T3 (see FIG. 5) described with respect to FIG. 5. However, the first transistor T1 and the third transistor T3 illustrated in FIG. 11A to FIG. 11C are not limited thereto, and may be different transistors among the above-described first to seventh transistors T1 to T7 (see FIG. 4), and are not limited to any one embodiment.

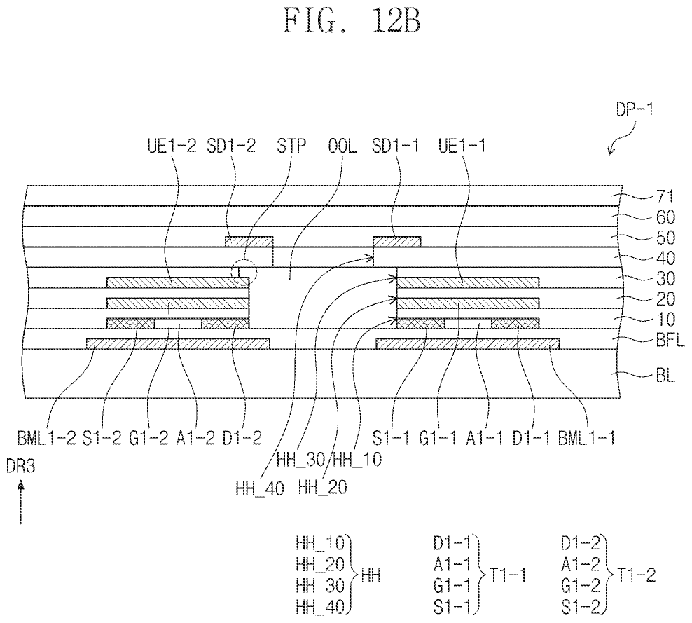

FIG. 12A and FIG. 12B are cross-sectional views of a display cross according to an embodiment of the inventive concept. Specifically, FIG. 12A and FIG. 12B are cross-sectional views of a display panel representing a case in which openings extending through multiple layers are aligned to form a single continuous opening.

Referring to FIG. 12A, a plurality of layer openings HH_10, HH_20, HH_30, and HH_40 respectively extending through the first inorganic layer 10, the second inorganic layer 20, the third inorganic layer 30, and the fourth inorganic layer 40 may be formed.

According to an embodiment of the inventive concept, in the process of forming each layer, and the process of forming each pattern of a transistor, an upper electrode, or a conductive pattern, each layer opening HH_10, HH_20, HH_30, or HH_40 is formed for each layer by using a mask, so that the layer openings continuously formed for each layer may provide an opening HH having a shape of a single body. At this time, the above-described half-tone mask may be used as the mask, but a common mask may be used as the mask without being limited thereto, and the inventive concept is not limited to any one embodiment.

According to an embodiment of the present invention, after forming the layer opening HH_10, HH_20, HH_30, or HH_40 in any one among the first to fourth inorganic layers, and before forming a new layer in an upper portion of the layer in which the layer opening HH_10, HH_20, HH_30, or HH_40 is formed, a step of disposing an organic material OOL covering the layer opening HH_10, HH_20, or HH_30 may be included.

When forming the layer opening HH_10, HH_20, HH_30, or HH_40 in any one among the first to fourth inorganic layers 10 to 40, a step STP may be formed. As an example, as illustrated in the drawing, the step STP may be formed in the third inorganic layer 30. When the fourth inorganic layer 40 is formed on the third inorganic layer 30 due to the step STP formed in the third inorganic layer 30, an upper surface of the fourth inorganic layer 40 may not have a desired shape. Since the upper surface of the fourth inorganic layer 40 does not have the desired shape, when forming the fourth preliminary pattern layer PPL-4 (see FIG. 11A) of FIG. 11A, it is possible to prevent a portion of the fourth preliminary pattern layer PPL-4 (see FIG. 11A) from being disconnected.

Before applying the fourth inorganic layer 40 on the third inorganic layer 30, the organic material OOL covers the layer opening HH_30, so that the organic material OOL can fill the opening and even out the step STP on the side walls of the opening HH_30. When the fourth inorganic layer 40 is formed on the third inorganic layer 30, it is possible to prevent the problem in which the upper surface of the fourth inorganic layer 40 has an undesired shape. As an example, the organic material OOL may come into direct contact with the layer opening HH_30.

The step STP is not limited to the third inorganic layer 30, and may be formed in other inorganic layers among the first to fourth inorganic layers 10 to 40, without being limited to any one embodiment. For example, without being limited to what is illustrated in the drawings, the step STP may be formed in the fourth inorganic layer 40 and the organic material OOL may come into direct contact with the layer opening HH_40 and is not limited to any one embodiment.

As an example, the organic material OOL covering the opening HH may include a non-photosensitive organic material. By allowing the organic material OOL to include a non-photosensitive organic material, it is possible to prevent the organic material OOL from being removed in a patterning process. By preventing the organic material OOL from being removed in the patterning process, it is possible to prevent the step STP compensated by the organic material OOL covering the opening HH from being exposed again.

As illustrated in the drawing, the organic material OOL may be accommodated in the opening HH, but without being limited thereto, may be disposed between adjacent layers among the first to fifth inorganic layers 10 to 50. For example, the organic material OOL may be disposed between the fourth inorganic layer 40 and the fifth inorganic layer 50, and the disposition relationship of the organic material OOL is not limited to any one embodiment.

Referring to FIG. 12B, the opening HH extending through the first inorganic layer 10, the second inorganic layer 20, the third inorganic layer 30, and the fourth inorganic layer 40 may be formed.

According to an embodiment of the inventive concept, in the step of forming each pattern of the transistors T1-1 and T1-2, the upper electrodes UE1-1 and UE1-2, or the conductive patterns SD1-1 and SD1-2, each of the layer openings HH_10, HH_20, HH_30, an HH_40 is formed for each layer by using each component as a mask, so that openings successively formed for each layer may provide an opening HH having a shape of a single body. At this time, the above-described half-tone mask may be used together, but a common mask may be used without being limited thereto, and the inventive concept is not limited to any one embodiment.

FIG. 12A and FIG. 12B illustrate that the layer openings HH_10, HH_20, HH_30, and HH_40 extending through each respective layer are successively formed, so that each of the layer openings HH_10, HH_20, HH_30, and HH_40 are connected to form one integrated opening HH. However, without being limited to what is illustrated in the drawings, the layer openings HH_10, HH_20, HH_30, and HH_40 may not be formed in at least one of the first to fourth inorganic layers 10 to 40, and the opening HH may not be formed successively, and is not limited to any one embodiment.

A display panel and a method for manufacturing the display panel according to an embodiment of the inventive concept may prevent cracks from being generated in inorganic layers by including openings for short-circuiting the inorganic layers.

A display panel and a method for manufacturing the display panel according to an embodiment of the inventive concept may prevent external impacts or cracks from being transmitted through inorganic layers by including openings for short-circuiting the inorganic layers.

Although the present invention has been described with reference to preferred embodiments of the present invention, it will be understood by those skilled in the art that various modifications and changes in form and details may be made therein without departing from the spirit and scope of the present invention as set forth in the following claims. Accordingly, the technical scope of the present invention is not intended to be limited to the contents set forth in the detailed description of the specification, but is intended to be defined by the appended claims.

What is claimed is:

1. A display panel comprising:
a base layer;
a transistor disposed on the base layer and including a semiconductor pattern and a gate;
an organic layer disposed on the transistor;
a plurality of inorganic layers disposed between the transistor and the organic layer;
a first conductive pattern disposed on any one of the inorganic layers; and
an organic light emitting element disposed on the organic layer,
wherein a first opening passing through at least one of the inorganic layers is defined, wherein the first opening does not overlap the first conductive pattern and the transistor on a plane.

2. The display panel of claim 1, wherein:
the transistor is provided in plurality; and
the first opening is positioned between adjacent transistors of the plurality of transistors.

3. The display panel of claim 2, further comprising:
a plurality of pixel circuits, each of which includes the transistors; and
a second opening positioned between adjacent pixel circuits of the plurality of pixel circuits.

4. The display panel of claim 1, wherein the first opening comprises:
a lower opening defined in a first inorganic layer of the inorganic layers; and
an upper opening defined in a second inorganic layer disposed on the first inorganic layer of the inorganic layers, the upper opening being connected to the lower opening,
wherein the diameter of the upper opening is greater than or equal to the diameter of the lower opening.

5. The display panel of claim 4, wherein one edge of the gate or one edge of the first conductive pattern is aligned with a wall of the upper opening.

6. The display panel of claim 4, wherein:
the gate and the first conductive pattern are disposed on the same layer; and
one side of the gate and one side of the first conductive pattern is aligned with the wall of the upper opening.

7. The display panel of claim 1, wherein:
the transistor comprises a first transistor including a first semiconductor pattern, a first gate, and an upper electrode, and a second transistor disposed spaced apart from the first transistor and including a second semiconductor pattern and a second gate; and
the inorganic layers comprise first to sixth layers sequentially stacked on the base layer,
wherein the first semiconductor pattern is disposed on the first layer, the first gate is disposed on the second layer, the upper electrode is disposed on the third layer, the second semiconductor pattern is disposed on the fourth layer, and the second gate is disposed on the fifth layer.

8. The display panel of claim 7, wherein:
the first semiconductor pattern comprises polysilicon; and
the second semiconductor pattern comprises an oxide.

9. The display panel of claim 7, further comprising a lower conductive layer overlapping the first semiconductor pattern, and disposed between the base layer and the first layer.

10. The display panel of claim 1, further comprising an organic material covering the first opening.

11. The display panel of claim 10, wherein the organic material is in direct contact with the first opening.

12. The display panel of claim 1, wherein the base layer comprises a folding region adjacent to a folding axis, and a non-folding region across the folding region from the folding axis,
wherein at least a portion of the first opening extends in a direction parallel to the folding axis.

13. The display panel of claim 1, further comprising a second conductive pattern disposed on any one among the inorganic layers, and spaced apart from the first conductive pattern,
wherein the first opening is positioned between the first conductive pattern and the second conductive pattern.

14. A method for manufacturing a display panel, the method comprising:
forming a transistor on a base layer;
forming inorganic layers on the base layer;
forming a first conductive pattern on any one of the inorganic layers;
forming an organic layer on at least one of the inorganic layers; and
forming an opening passing through at least one of the inorganic layers, and not overlapping the transistor and the first conductive pattern, wherein the forming of the opening is performed before the forming of the organic layer on the inorganic layers.

15. The method of claim 14, wherein the forming of the opening comprises:
etching a first inorganic layer among the inorganic layers to form a lower opening; and
etching a second inorganic layer disposed on the first inorganic layer to form an upper opening overlapping the lower opening.

16. The method of claim 15, wherein a half-tone mask is used to form the upper opening having a diameter different from that of the lower opening.

17. The method of claim 14, wherein the first conductive pattern is used as a mask to etch at least one among the inorganic layers, thereby forming the opening.

18. The method of claim 14, wherein the first conductive pattern and the opening are simultaneously formed.

19. The method of claim 14, wherein the forming of the transistor comprises:
forming a semiconductor pattern on a first inorganic layer of the inorganic layers;
forming a second inorganic layer on the first inorganic layer; and
forming a gate on the second inorganic layer,
wherein the forming of the opening further includes etching the second inorganic layer by using the gate as a mask.

20. The method of claim 14, wherein the forming of the transistor comprises:
forming a semiconductor pattern on a first inorganic layer among the inorganic layers;
forming a second inorganic layer on the first inorganic layer; and
forming a gate on the second inorganic layer, wherein the gate and the opening are simultaneously formed.
